(19) United States
(12) Patent Application Publication
(10) Pub. No.: US 2025/0275336 A1
(43) Pub. Date: Aug. 28, 2025

(54) LIGHT EMITTING ELEMENT AND ELECTRONIC DEVICE INCLUDING THE SAME

(71) Applicant: Samsung Display Co., LTD., Yongin-si (KR)

(72) Inventors: Sun PARK, Yongin-si (KR); Hoo Keun PARK, Yongin-si (KR); Kyung Rock SON, Yongin-si (KR); Hui Won YANG, Yongin-si (KR); Jae Phil LEE, Yongin-si (KR)

(73) Assignee: Samsung Display Co., LTD., Yongin-si (KR)

(21) Appl. No.: 18/970,217

(22) Filed: Dec. 5, 2024

(30) Foreign Application Priority Data
Feb. 23, 2024 (KR) 10-2024-0026548

(51) Int. Cl. H10H 29/49; H10H 29/24

(52) U.S. Cl. CPC H10H 29/49; H10H 29/24

(57) ABSTRACT

A light emitting element includes a light emitting stack member including a first semiconductor layer, an active layer, and a second semiconductor layer, which are sequentially stacked in a thickness direction, an insulative film covering a portion of an outer circumferential surface of the light emitting stack member, a first bonding electrode which includes a first indented portion indented in the thickness direction and is electrically connected to the first semiconductor layer in an area in which the first indented portion is formed, and a second bonding electrode which is spaced apart from the first bonding electrode and is electrically connected to the second semiconductor layer. The first bonding electrode includes a first outgassing path which is indented in the thickness direction and extends from the first indented portion to a side surface of the first bonding electrode.

### CROSS-REFERENCE TO RELATED APPLICATION(S)

This application claims priority to and benefits of Korean patent application No. 10-2024-0026548 under 35 U.S.C. § 119, filed on Feb. 23, 2024, in the Korean Intellectual Property Office, the entire contents of which are incorporated herein by reference.

### BACKGROUND

### 1. Technical Field

Embodiments relate to a light emitting element and an electronic device including the light emitting element.

### 2. Description of the Related Art

A display device is a device which displays an image by combining lights emitted from pixels. Each of the pixels includes a light emitting element emitting light. The light emitting element may include a bonding electrode bonded to an electrode (e.g., an anode electrode and/or a cathode electrode) electrically connected to a pixel circuit of the display device. In case that the bonding reliability of the light emitting element is deteriorated, the quality of the display device may be deteriorated.

### SUMMARY

Embodiments provide a light emitting element capable of improving bonding reliability.

However, embodiments are not limited to those set forth herein. The above and other embodiments will become more apparent to one of ordinary skill in the art to which the disclosure pertains by referencing the detailed description of the disclosure given below.

In accordance with an aspect of the disclosure, there is provided a light emitting element including: a light emitting stack member including a first semiconductor layer, an active layer, and a second semiconductor layer, which are sequentially stacked in a thickness direction; an insulative film covering a portion of an outer circumferential surface of the light emitting stack member; a first bonding electrode including a first indented portion indented in the thickness direction, the first bonding electrode being electrically connected to the first semiconductor layer in an area in which the first indented portion is formed; and a second bonding electrode spaced apart from the first bonding electrode, the second bonding electrode being electrically connected to the second semiconductor layer, wherein the first bonding electrode may include a first outgassing path which is indented in the thickness direction and extends from the first indented portion to a side surface of the first bonding electrode.

The first outgassing path may be provided in plurality.

At least some of the plurality of first outgassing paths may extend in different directions.

The insulative film may include a first penetration hole exposing a portion of the first semiconductor layer. The first penetration hole may overlap the first indented portion.

The second bonding electrode may include a second indented portion indented in the thickness direction, and may be electrically connected to the second semiconductor layer in an area in which the second indented portion is formed.

The second bonding electrode may include a second outgassing path which is indented in the thickness direction and extends from the second indented portion to a side surface of the second bonding electrode.

The second outgassing path may be provided in plurality.

At least some of the plurality of second outgassing paths may extend in different directions.

The first semiconductor layer and the active layer may include a second penetration hole exposing a portion of the second semiconductor layer. The second penetration hole may overlap the second indented portion.

The insulative film may cover (e.g., directly cover) inner side surfaces of the first semiconductor layer and the active layer, which include the second penetration hole.

In accordance with another aspect of the disclosure, there is provided a light emitting element including: a light emitting stack member including a first semiconductor layer, an active layer, and a second semiconductor layer, which are sequentially stacked in a thickness direction; an insulative film covering a portion of an outer circumferential surface of the light emitting stack member; and a bonding electrode including an indented portion indented in the thickness direction and an outgassing path indented in the thickness direction, the bonding electrode being electrically connected to the first semiconductor layer in an area in which the indented portion is formed, wherein the outgassing path may extend from the indented portion to a side surface of the bonding electrode.

The outgassing path may be provided in plurality.

The insulative film may include a penetration hole exposing a portion of the first semiconductor layer. The penetration hole may overlap the indented portion.

The light emitting stack member may have a pillar shape.

In accordance with still another aspect of the disclosure, there is provided a light emitting element including: a light emitting stack member including a first semiconductor layer, an active layer, and a second semiconductor layer, which are sequentially stacked in a thickness direction; an insulative film covering a portion of a lower surface of the first semiconductor layer; a first bonding electrode extending from the insulative film covering the portion of the lower surface of the first semiconductor layer to a side surface of the light emitting stack member, the first bonding electrode being electrically connected to the first semiconductor layer; and a second bonding electrode extending from the insulative film covering the portion of the lower surface of the first semiconductor layer to an opposite side surface of the light emitting stack member, the second bonding electrode being electrically connected to the second semiconductor layer, wherein, in the first bonding electrode, a first step difference may be formed in the thickness direction between a (1-1)th bonding portion overlapping the insulative film covering the portion of the lower surface of the first semiconductor layer and a (1-2)th bonding portion adjacent to the side surface of the light emitting stack member.

The insulative film may expose another portion of the lower surface of the first semiconductor layer, which is adjacent to the side surface of the light emitting stack member.

The (1-2)th bonding portion may overlap the another portion of the lower surface of the first semiconductor layer.

In the second bonding electrode, a second step difference may be formed in the thickness direction between a (2-1)th bonding portion overlapping the insulative film covering the portion of the lower surface of the first semiconductor layer and a (2-2)th bonding portion adjacent to the opposite side surface of the light emitting stack member.

The second semiconductor layer may include a first portion overlapping the first semiconductor layer and the active layer in plan view and a second portion which is disposed on the first portion and has an area, which is greater than an area of the first portion in plan view. In an area adjacent to the opposite side surface of the light emitting stack member, the second portion may not overlap the first portion in plan view. The (2-2)th bonding portion may be electrically connected to the second portion not overlapping the first portion under the second portion.

The second step difference may be greater than the first step difference.

In accordance with an aspect of the disclosure, there is provided an electronic device including: a processor to provide input image data; and a display device to display an image based on the input image data. The display device may include a light emitting element. The light emitting element may include: a light emitting stack member including a first semiconductor layer, an active layer, and a second semiconductor layer, which are sequentially stacked in a thickness direction; an insulative film covering a portion of an outer circumferential surface of the light emitting stack member; a first bonding electrode including a first indented portion indented in the thickness direction, the first bonding electrode being electrically connected to the first semiconductor layer in an area in which the first indented portion is formed; and a second bonding electrode spaced apart from the first bonding electrode, the second bonding electrode being electrically connected to the second semiconductor layer, wherein the first bonding electrode may include a first outgassing path which is indented in the thickness direction and extends from the first indented portion to a side surface of the first bonding electrode.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic block diagram illustrating a display device in accordance with embodiments.

FIG. 2 is a schematic block diagram illustrating any one sub-pixel among sub-pixels included in the display device shown in FIG. 1.

FIG. 3 is a schematic plan view illustrating a display panel of the display device shown in FIG. 1.

FIG. 4 is a schematic sectional view illustrating an embodiment of the display panel shown in FIG. 3.

FIG. 5 is a schematic sectional view illustrating another embodiment of the display panel shown in FIG. 3.

FIG. 6 is a schematic plan view illustrating a first embodiment of a light emitting element included in a sub-pixel shown in FIG. 3.

FIG. 7 is a schematic sectional view taken along line I1-I1′ shown in FIG. 6.

FIGS. 8 and 9 are sectional views taken along line I2-I2′ shown in FIG. 6.

FIGS. 10 and 11 are schematic sectional views illustrating a bonding process of bonding the light emitting element shown in FIG. 6.

FIG. 12 is a schematic plan view illustrating an embodiment in which the light emitting element shown in FIG. 6 has a plurality of outgassing paths.

FIG. 13 is a schematic sectional view taken along line I3-I3′ shown in FIG. 12.

FIG. 14 is a schematic plan view illustrating an embodiment of a pixel to which the light emitting element shown in FIG. 6 is applied.

FIG. 15 is a schematic sectional view taken along line Y1-Y1′ shown in FIG. 14.

FIG. 16 is a schematic sectional view taken along line X1-X1′ shown in FIG. 14.

FIG. 17 is a schematic plan view illustrating a second embodiment of the light emitting element included in the sub-pixel shown in FIG. 3.

FIG. 18 is a schematic sectional view taken along line I4-I4′ shown in FIG. 17.

FIG. 19 is a schematic plan view illustrating an embodiment of a pixel to which the light emitting element shown in FIG. 17 is applied.

FIG. 20 is a schematic sectional view taken along line Y2-Y2′ shown in FIG. 19.

FIG. 21 is a sectional view taken along line X2-X2′ shown in FIG. 19.

FIG. 22 is a schematic plan view illustrating a third embodiment of the light emitting element included in the sub-pixel shown in FIG. 3.

FIG. 23 is a schematic sectional view taken along line I5-I5′ shown in FIG. 22.

FIGS. 24 and 25 are schematic sectional views taken along line I6-I6′ shown in FIG. 22.

FIG. 26 is a schematic plan view illustrating an embodiment of a pixel to which the light emitting element shown in FIG. 22 is applied.

FIG. 27 is a schematic sectional view taken along line X3-X3′ shown in FIG. 26.

FIG. 28 is a schematic block diagram illustrating a display system in accordance with an embodiment.

FIGS. 29 to 32 are schematic perspective views illustrating application examples of the display system shown in FIG. 28.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

For example, the embodiments of the disclosure are described here with reference to schematic diagrams of embodiments (and an intermediate structure) of the disclosure, so that changes in a shape as shown due to, for example, manufacturing technology and/or a tolerance may be expected. Therefore, the embodiments shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

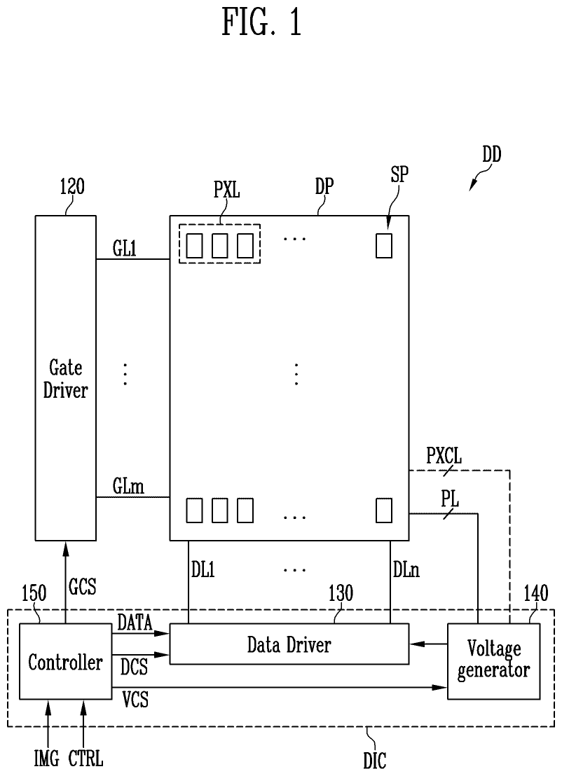

FIG. 1 is a schematic block diagram illustrating a display device in accordance with embodiments.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels among the sub-pixels SP may form a pixel PXL. For example, the pixel PXL may include three sub-pixels as shown in FIG. 1. The pixel PXL may emit lights of various colors with various luminances according to a combination of lights emitted from the sub-pixels included in the pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be disposed at a side of the display panel DP. However, embodiments are not limited thereto. For example, the gate driver 120 may be divided into two or more drivers which are physically and/or logically divided, and these drivers may be disposed at a side of the display panel DP and the other side of the display panel DP, which is opposite to the side. In some embodiments, the gate driver 120 may be disposed in various forms at the periphery of the display panel DP.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn by using the received voltages. In case that a gate signal is applied to each of the first to m-th gate lines GL1 to GLm, data signals corresponding to the image data DATA may be applied to the first to n-th data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages and provide the generated voltages to components of the display device DD. The voltage generator 140 may generate a plurality of voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

For example, the voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a selected reference voltage may be applied to the first to n-th data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on a single integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in a single driver integrated circuit DIC. In other embodiments, at least one of the data driver 130, the voltage generator 140, and the controller 150 may be provided (or formed) as a component distinguished from the driver integrated circuit DIC.

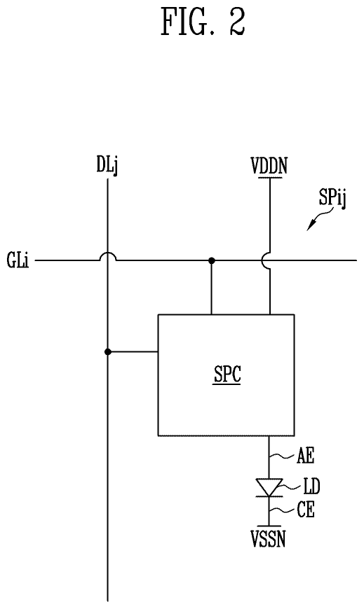

FIG. 2 is a schematic block diagram illustrating any one sub-pixel among the sub-pixels included in the display device shown in FIG. 1. In FIG. 2, a sub-pixel SP1j arranged on an i-th row (i is an integer which is greater than or equal to 1 and is smaller than or equal to m) and a j-th column (j is an integer which is greater than or equal to 1 and is smaller than or equal to n) among the sub-pixels SP shown in FIG. 1 is illustrated.

Referring to FIG. 2, the sub-pixel SP1j may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may emit light according to a current flowing from the anode electrode AE to the cathode electrode CE.

The sub-pixel circuit SPC may be connected to an i-th gate line GLi among the first to m-th gate lines GL1 to GLm shown in FIG. 1 and a j-th data line DLj among the first to n-th data lines DL1 to DLn shown in FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. In embodiments, the transistors of the sub-pixel circuit SPC may include a Metal Oxide Silicon Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, and the like.

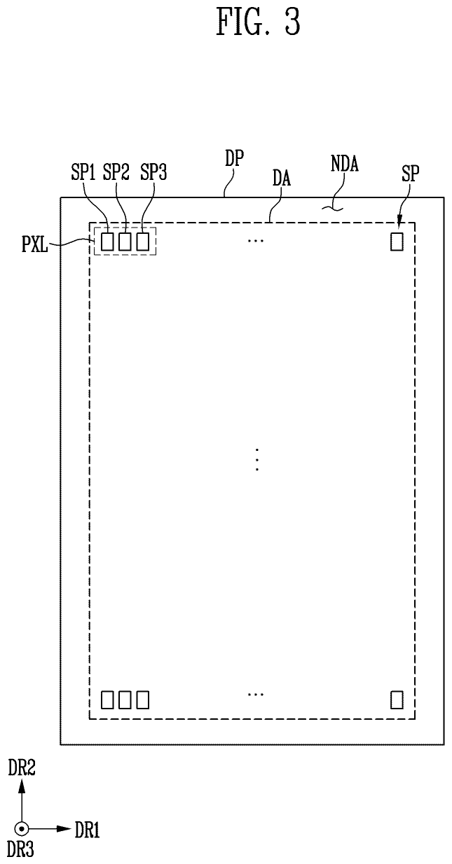

FIG. 3 is a schematic plan view illustrating the display panel DP of the display device shown in FIG. 1.

Referring to FIG. 3, a display panel DP may include a display area DA and a non-display area NDA. The display panel DP may display an image through the display area DA. The non-display area NDA may be disposed at the periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may form a single pixel PXL. In FIG. 3, it is illustrated that the pixel PXL includes three sub-pixels SP1, SP2, and SP3. However, embodiments are not limited thereto. For example, the pixel PXL may include two sub-pixels. Hereinafter, for convenience of description, it is assumed that the pixel PXL includes first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and simple description, it is assumed that the first sub-pixel SP1 generates light of a red color, the second sub-pixel SP2 generates light of a green color, and the third sub-pixel SP3 generates light of a blue color.

Each of the first to third sub-pixels SP1, SP2, and SP3 may include at least one light emitting element that generates light. In embodiments, light emitting elements of the first to third sub-pixels SP1, SP2, and SP3 may generate light of the same color. For example, the light emitting elements of the first to third sub-pixels SP1, SP2, and SP3 may generate light of a blue color. In other embodiments, the light emitting elements of the first to third sub-pixels SP1, SP2, and SP3 may generate lights of different colors. For example, the light emitting elements of the first to third sub-pixels SP1, SP2, and SP3 may generate lights a red color, a green color, and a blue color, respectively.

Self-luminous display panels, such as alight emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to m-th gate lines GL1 to GLm, the first to n-th data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The controller 150, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into a single integrated circuit distinguished from the display panel DP.

In embodiments, the display area DA may have various shapes. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include materials having flexibility.

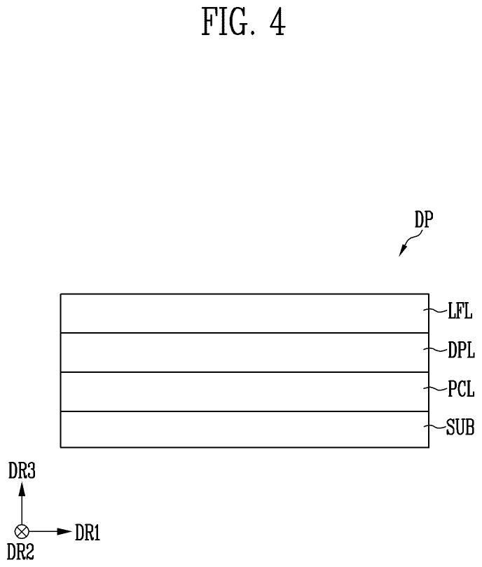

FIG. 4 is a schematic sectional view illustrating an embodiment of the display panel DP shown in FIG. 3.

Referring to FIG. 4, a display panel DP may include a substrate SUB, and a pixel circuit layer PCL, a display panel layer DPL, and a light functional layer LFL, which are sequentially stacked in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In still another example, the substrate SUB may include a silicon wafer substrate formed by a semiconductor process.

In embodiments, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may function as circuit elements, lines, and the like.

The circuit elements of the pixel circuit layer PCL may form a sub-pixel circuit SPC of each of the sub-pixels SP shown in FIG. 3. For example, the circuit elements of the pixel circuit layer PCL may be provided (or formed) as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines, which are necessary for driving the display panel layer DPL.

The display panel layer DPL may be disposed on the pixel circuit layer PCL. The display panel layer DPL may include light emitting elements of the sub-pixels SP.

The light functional layer LFL may be disposed on the display panel layer DPL. The light functional layer LFL may include light conversion patterns having color conversion particles and/or light scattering particles. For example, color conversion particles may include quantum dots. The quantum dots may change a wavelength (or color) of light emitted from the display panel layer DPL. The light functional layer LFL may further include light scattering patterns having light scattering particles. In another example, the light conversion patterns and the light scattering patterns may be omitted.

The light functional layer LFL may further include a color filter layer including color filters. The color filter may selectively transmit light having a specific wavelength (or specific color) therethrough. In another example, the color filter layer may be omitted.

A window for protecting an exposed surface (or top surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed by a continuous process or an adhesive process using an adhesive layer. The whole or a portion of the window may have flexibility.

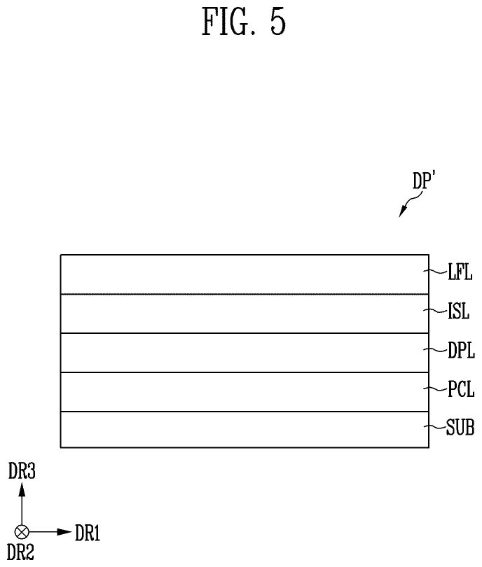

FIG. 5 is a schematic sectional view illustrating another embodiment of the display panel shown in FIG. 3.

Referring to FIG. 5, a display panel DP′ may include a substrate SUB, a pixel circuit layer PCL, a display panel layer DPL, an input sensing layer ISL, and a light functional layer LFL. The substrate SUB, the pixel circuit layer PCL, the display panel layer DPL, and the light functional layer LFL may be formed subsequently identical (or similar) to the substrate SUB, the pixel circuit layer PCL, the display panel layer DPL, and the light functional layer LFL, which are described with reference to FIG. 4, respectively. Therefore, descriptions of overlapping portions will be omitted for descriptive convenience.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

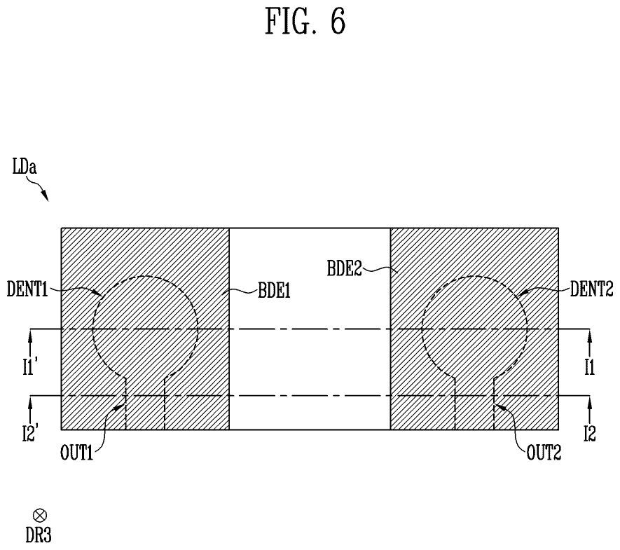

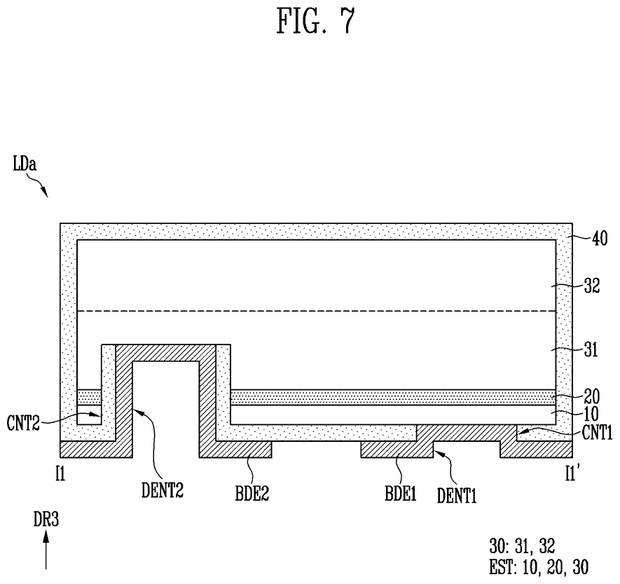

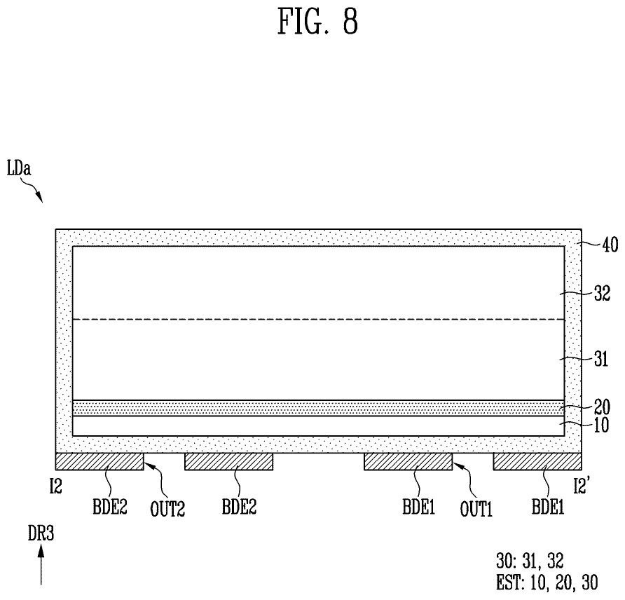

FIG. 6 is a schematic plan view illustrating a first embodiment of a light emitting element included in the sub-pixel shown in FIG. 3. FIG. 7 is a schematic sectional view taken along line I1-I1′ shown in FIG. 6. FIG. 8 is a schematic sectional view taken along line I2-I2′ shown in FIG. 6.

Referring to FIGS. 6 to 8, a light emitting element LDa may include a light emitting stack member (or light emitting stack structure) EST, a first bonding electrode BDE1, a second bonding electrode BDE2, and an insulative film 40. The light emitting stack member EST may include a first semiconductor layer 10, an active layer 20, and a second semiconductor layer 30, which are sequentially stacked in the third direction DR3. The third direction DR3 may be designated as a thickness direction.

The first semiconductor layer 10 may provide (or include) holes. The first semiconductor layer 10 may have a first polarity. For example, the first semiconductor layer 10 may include at least one p-type semiconductor layer. For example, the first semiconductor layer 10 may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a first conductive dopant (or p-type dopant) such as magnesium (Mg), zinc (Zn), calcium (Ca), strontium (Sr) or barium (Ba). However, the material of the first semiconductor layer 10 is not limited thereto. For example, various materials may form the first semiconductor layer 10. In an embodiment, the first semiconductor layer 10 may include a gallium nitride (GaN) semiconductor material doped with the first conductive dopant (or n-type dopant).

The active layer 20 may be interposed between the first semiconductor layer 10 and the second semiconductor layer 30 to provide an area in which electrons and holes are recombined. As electrons and holes are recombined in the active layer 20, light may be generated, which has a level changed to a low energy level and has a wavelength corresponding to the low energy level. The active layer 20 may be formed in a single quantum well structure or a multi-quantum well structure. In case that the active layer 20 is formed in the multi-quantum well structure, a unit including a barrier layer, a strain reinforcing layer, and a well layer may be repeatedly stacked, to form the active layer 20. However, the active layer 20 is not limited to the above-described structure.

The second semiconductor layer 30 may provide electrons. The second semiconductor layer 30 may have a second polarity different from the first polarity. For example, the second semiconductor layer 30 may include at least one n-type semiconductor layer. For example, the second semiconductor layer 30 may include any one semiconductor material among gallium nitride (GaN), aluminum gallium nitride (AlGaN), indium gallium nitride (InGaN), aluminum nitride (AlN), and indium nitride (InN), and be an n-type semiconductor layer doped with a second conductive dopant (or n-type dopant) such as silicon (Si), germanium (Ge) or tin (Sn). However, the material of the second semiconductor layer 30 is not limited thereto. For example, various materials may form the second semiconductor layer 30. In an embodiment, the second semiconductor layer 30 may include a gallium nitride (GaN) semiconductor material doped with the second conductive dopant (or n-type dopant).

In some embodiments, the second semiconductor layer 30 may include a first doping portion 31 disposed on the active layer 20 and a second doping portion 32 disposed on the first doping portion 31. The first doping portion 31 may be an area doped with a dopant at a relatively high concentration. The second doping portion 32 may be area doped with the dopant at a relatively low concentration or substantially undoped with the dopant. For example, a first average doping concentration at the first doping portion 31 may be higher than a second average doping concentration at the second doping portion 32. The first doping portion 31 and the second doping portion 32 may be integral with each other such that the second semiconductor layer 30 may be formed.

The insulative film 40 may cover at least a portion of an outer circumferential surface of the light emitting stack member EST. For example, the insulative film 40 may cover at least a side surface of the active layer 20. The insulative film 40 may include a transparent insulative material. The insulative film 40 may prevent an electric short circuit which occurs in case that the active layer 20 is in contact with another component having conductivity. In embodiments, the insulative film 40 may have a multi-layer structure including a plurality of layers including a transparent insulative material.

The first bonding electrode BDE1 may be disposed under the first semiconductor layer 10. The first bonding electrode BDE1 may be connected (e.g., electrically connected) to the first semiconductor layer 10. The first bonding electrode BDE1 may include, for example, a eutectic metal.

In embodiments, the insulative film 40 may define (or include) a first penetration hole CNT1 exposing a portion of a bottom surface of the first semiconductor layer 10. The first bonding electrode BDE1 may be connected (e.g., electrically connected) to the first semiconductor layer 10 through the first penetration hole CNT1.

In embodiments, the first bonding electrode BDE1 may define (or include) a first indented portion DENT1 indented in the third direction DR3. The first indented portion DENT1 may overlap the first penetration hole CNT1. In an area in which the first indented portion DENT1 is defined (or formed), the first bonding electrode BDE1 may be connected (e.g., electrically connected) to the first semiconductor layer 10. For example, as shown in FIG. 7, the first bonding electrode BDE1 in the area in which the first indented portion DENT1 is defined (or formed) may be in contact with (e.g., electrically connected to) the first semiconductor layer 10.

The second bonding electrode BDE2 may be disposed and spaced apart from the first bonding electrode BDE1. The second bonding electrode BDE2 may be connected (e.g., electrically connected) to the second semiconductor layer 30. The second bonding electrode BDE2 may include, for example, a eutectic metal.

In embodiments, the first semiconductor layer 10 and the active layer 20 may define (or include) a second penetration hole CNT2 exposing a portion of the second semiconductor layer 30. The second bonding electrode BDE2 may be connected (e.g., electrically connected) to the second semiconductor layer 30 through the second penetration hole CNT2. The second penetration hole CNT2 may expose the first doping portion 31 having a relatively high doping concentration. For example, a portion of the first doping portion 31 adjacent to the active layer 20 along with the first semiconductor layer 10 and the active layer 20 may define (or include) the second penetration hole CNT2.

The insulative film 40 may cover (e.g., directly cover) inner side surfaces of the first semiconductor layer 10 and the active layer 20, which define (or include) the second penetration hole CNT2. For example, in the second penetration hole CNT2, the insulative film 40 may be interposed between the second bonding electrode BDE2 and the inner side surfaces of the first semiconductor layer 10 and the active layer 20. Accordingly, an electric short circuit may be prevented, which occurs in case that the second bonding electrode BDE2 is in contact with the first semiconductor layer 10 and the active layer 20.

In embodiments, the second bonding electrode BDE2 may define (or include) a second indented portion DENT2 indented in the third direction DR3. The second indented portion DENT2 may overlap the second penetration hole CNT2. In an area in which the second indented portion DENT2 is defined (or formed), the second bonding electrode BDE2 may be connected (e.g., electrically connected) to the second semiconductor layer 30. For example, as shown in FIG. 7, the second bonding electrode BDE2 in the area in which the second indented portion DENT2 is defined (or formed) may be in contact with (e.g., electrically connected to) the first doping portion 31.

As described above, the first indented portion DENT1 may be defined (or formed) in the first bonding electrode BDE1, and the second indented portion DENT2 may be defined (or formed) in the second bonding electrode BDE2. The first bonding electrode BDE1 and the second bonding electrode BDE2 may be bonded on electrodes (e.g., AE1, CE, RFE1, RFE2, and the like) connected to the sub-pixel circuit SPC (see FIG. 2) of the display device DD, which will be described later.

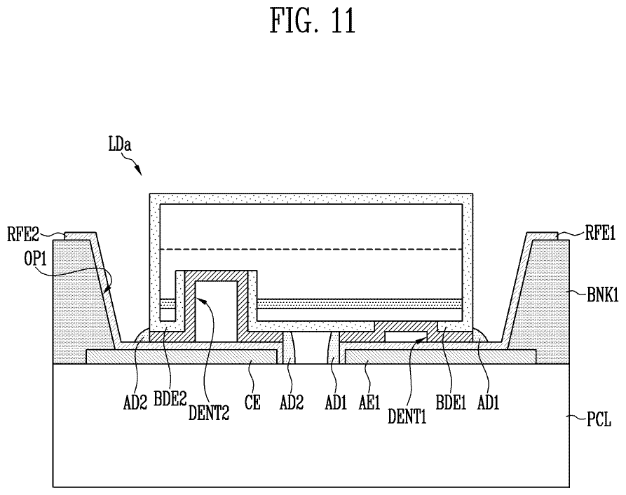

A closed space including the first indented portion DENT1 may be defined (or formed) between the first bonding electrode BDE1 and an electrode (e.g., RFE1 shown in FIG. 11) provided under the first bonding electrode BDE1. For example, a closed space including the second indented portion DENT2 may be defined (or formed) between the second bonding electrode BDE2 and an electrode (e.g., RFE2 shown in FIG. 11) provided under the second bonding electrode BDE2. Air existing in the closed spaces may cause deterioration of the bonding reliability of the light emitting element LDa. For example, under various process conditions, the volume of the air existing in the closed spaces may increase, and accordingly, a problem may occur in that the light emitting element LDa bonded to the electrodes is separated.

In order to prevent the deterioration, the first bonding electrode BDE1 may define (or include) a first outgassing path OUT1, and the second bonding electrode BDE2 may define (or include) a second outgassing path OUT2. Hereinafter, the first and second outgassing paths OUT1 and OUT2 will be described in detail.

The first bonding electrode BDE1 may define (or form) the first outgassing path OUT1 indented in the third direction DR3. For example, the first bonding electrode BDE1 may expose the insulative film 40 covering the bottom surface of the first semiconductor layer 10 in an area in which the first outgassing path OUT1 is defined (or formed). In accordance with embodiments, the insulative film 40 may be further removed in the area in which the first outgassing path OUT1 is defined (or formed). For example, the first semiconductor layer 10 may be exposed in the area in which the first outgassing path OUT1 is defined (or formed). The first outgassing path OUT1 may extend from the first indented portion DENT1 to a side surface of the first bonding electrode BDE1. Accordingly, air existing in a space defined (or formed) between the first bonding electrode BDE1 and the electrode (e.g., RFE1 shown in FIG. 11) provided under the first bonding electrode BDE1 may be exhausted to the outside through the first outgassing path OUT1. Thus, the bonding reliability of the light emitting element LDa may be improved.

The second bonding electrode BDE2 may define (or include) the second outgassing path OUT2 indented in the third direction DR3. For example, the second bonding electrode BDE2 may expose the insulative film 40 covering the bottom surface of the first semiconductor layer 10 in an area in which the second outgassing path OUT2 is defined (or formed). In accordance with embodiments, the insulative film 40 may be further removed in the area in which the second outgassing path OUT2 is defined (or formed). For example, the first semiconductor layer 10 may be exposed in the area in which the second outgassing path OUT2 is defined (or formed). The second outgassing path OUT2 may extend from the second indented portion DENT2 to a side surface of the second bonding electrode BDE2. Accordingly, air existing in a space defined (or formed) between the second bonding electrode BDE2 and the electrode (e.g., RFE2 shown in FIG. 11) provided under the second bonding electrode BDE2 may be exhausted to the outside through the second outgassing path OUT2. Thus, the bonding reliability of the light emitting element LDa may be improved.

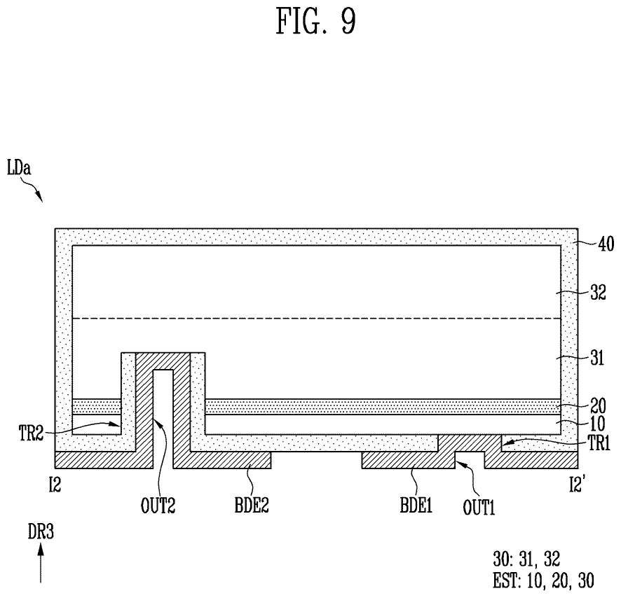

FIG. 9 is a schematic sectional view taken along the line I2-I2′ shown in FIG. 6. FIG. 9 is a schematic sectional view illustrating a modified embodiment of the outgassing paths which have been described with reference to FIGS. 6 and 8.

Hereinafter, portions different from those of the embodiment which has been described with reference to FIGS. 6 to 8 will be described, and portions of which description is omitted are the same as (or similar to) the above-described portions.

Referring to FIG. 9, the insulative film 40 may define (or include) a first trench TR1 exposing a portion of the bottom surface of the first semiconductor layer 10. In embodiments, the first trench TR1 may be integral with the first penetration hole CNT1.

The first bonding electrode BDE1 may define (or include) a first outgassing path OUT1 indented in the third direction DR3 in an area in which the first bonding electrode BDE1 overlaps the first trench TR1. In the area in which the first outgassing path OUT1 is defined (or formed), the first bonding electrode BDE1 may be electrically connected to (or in contact with) the first semiconductor layer 10 exposed by the first trench TR1. The first outgassing path OUT1 may extend from the first indented portion DENT1 to the side surface of the first bonding electrode BDE1. For example, the first outgassing path OUT1 may have various shapes in which air existing in a space surrounded by the first indented portion DENT1 and the electrode (e.g., RFE1 shown in FIG. 11) may be exhausted.

The first semiconductor layer 10 and the active layer 20 may define (or include) a second trench TR2 exposing a portion of the second semiconductor layer 30. In accordance with embodiments, a portion of the first doping portion 31 adjacent to the active layer 20 along with the first semiconductor layer 10 and the active layer 20 may define (or include) the second trench TR2. In embodiments, the second trench TR2 may be integral with the second penetration hole CNT2.

The second bonding electrode BDE2 may define (or include) a second outgassing path OUT2 indented in the third direction DR3 in an area in which the second bonding electrode BDE2 overlaps the second trench TR2. In the area in which the second outgassing path OUT2 is defined (or formed), the second bonding electrode BDE2 may be electrically connected to (or in contact with) the second semiconductor layer 30 exposed by the second trench TR2. The inner side surfaces of the first semiconductor layer 10 and the active layer 20, which define (or include) the second trench TR2, may be covered (e.g., directly covered) by the insulative film 40. For example, the insulative film 40 may be interposed between the second bonding electrode BDE2 and the inner side surfaces of the first semiconductor layer 10 and the active layer 20. The second outgassing path OUT2 may extend from the second indented portion DENT2 to the side surface of the second bonding electrode BDE2. For example, the second outgassing path OUT2 may have various shapes in which air existing in a space surrounded by the second indented portion DENT2 and the electrode (e.g., RFE2 shown in FIG. 11) may be exhausted.

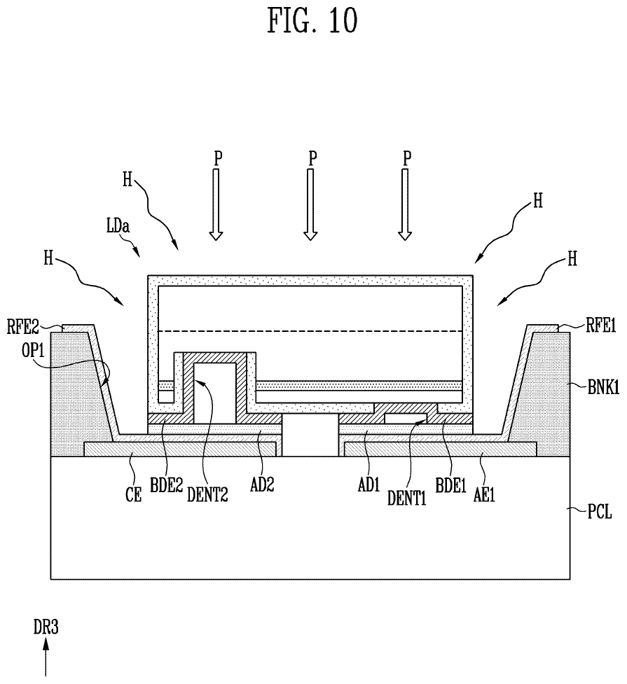

FIGS. 10 and 11 are schematic sectional views illustrating a bonding process of bonding the light emitting element shown in FIG. 6.

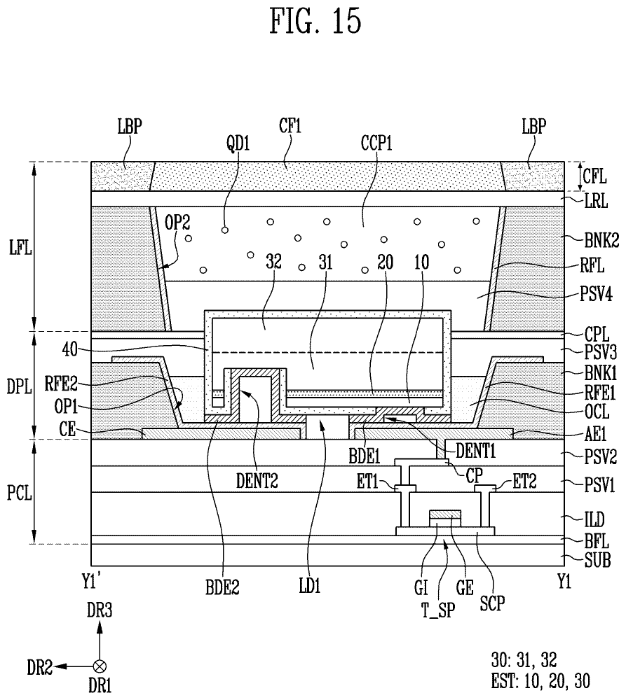

Referring to FIG. 10, a pixel circuit layer PCL, a first anode electrode AE1, and a cathode electrode CE may be provided. Various components of the display device DD may be further provided on the first anode electrode AE1 and the cathode electrode. For example, a first bank BNK1 having a first opening OP1 exposing portions of the first anode electrode AE1 and the cathode electrode CE may be provided on the first anode electrode AE1 and the cathode electrode CE. A first reflective electrode RFE1 may be disposed on the exposed portion of the first anode electrode AE1 and a side surface of the first bank BNK1 which is adjacent to the exposed portion of the first anode electrode AE1. A second reflective electrode RFE2 may be disposed on the exposed portion of the cathode electrode CE and a side surface of the first bank BNK1 which is adjacent to the exposed portion of the cathode electrode CE. The pixel circuit layer PCL, the first anode electrode AE1, the cathode electrode CE, the first reflective electrode RFE1, and the second reflective electrode RFE2 will be described in detail later with reference to FIG. 15.

In the first opening OP1, a first adhesive layer AD1 may be provided on the first reflective electrode RFE1. In the first opening OP1, a second adhesive layer AD2 may be provided on the second reflective electrode RFE2. The first and second adhesive layers AD1 and AD2 may provide fixing power (or adhesive strength) to the light emitting element LDa. In accordance with embodiments, the first and second adhesive layers AD1 and AD2 may further include a metal material such as SnAgCu (SAC) for bonding of the first and second bonding electrodes BDE1 and BDE2 and the first and second reflective electrodes RFE1 and RFE2.

In the first opening OP1, the light emitting element LDa may be provided on the first anode electrode AE1 and the cathode electrode CE. As the method of providing the light emitting element LDa, various methods previously known in the art may be used without restriction. The first bonding electrode BDE1 may be provided on the first adhesive layer AD1, and the second bonding electrode BDE2 may be provided on the second adhesive layer AD2.

After that, for bonding of the light emitting element LDa, sufficient heat H may be applied to the light emitting element LDa with applying pressure P in a direction opposite to the third direction DR3.

Referring to FIG. 11, the first and second adhesive layers AD1 and AD2 may be squeezed out by the pressure P (see FIG. 10), the first bonding electrodes BDE1 and BDE2 may be in contact with the first and second reflective electrodes RFE1 and RFE2, respectively. For example, the first bonding electrodes BDE1 and BDE2 may be bonded to the first and second reflective electrodes RFE1 and RFE2 by the head H (see FIG. 10). The remaining first and second adhesive layers AD1 and AD2 may be removed or form a portion of an overcoat layer OCL (see FIG. 15) which will be described later.

Accordingly, a first space surrounded by the first reflective electrode RFE1 and the first indented portion DENT1 of the first bonding electrode BDE1 may be defined (or formed), and a second space surrounded by the second reflective electrode RFE2 and the second indented portion DENT2 of the second bonding electrode BDE2 may be defined (or formed).

For example, the first bonding electrode BDE1 may further define (or include) the first outgassing path OUT1 (see FIGS. 8 and 9), and the second bonding electrode BDE2 may further define (or include) the second outgassing path OUT2 (see FIGS. 8 and 9). The first outgassing path OUT1 may enable communication between the first space and the outside, thereby preventing the first space from becoming a closed space (or closed environment). The second outgassing path OUT2 may enable communication between the second space and the outside, thereby preventing the second space and the outside, thereby preventing from becoming a closed space (or closed environment). Accordingly, deterioration of bonding reliability may be prevented or minimized, thereby providing open spaces (not closed spaces) through the first outgassing path OUT1 and the second outgassing path OUT2.

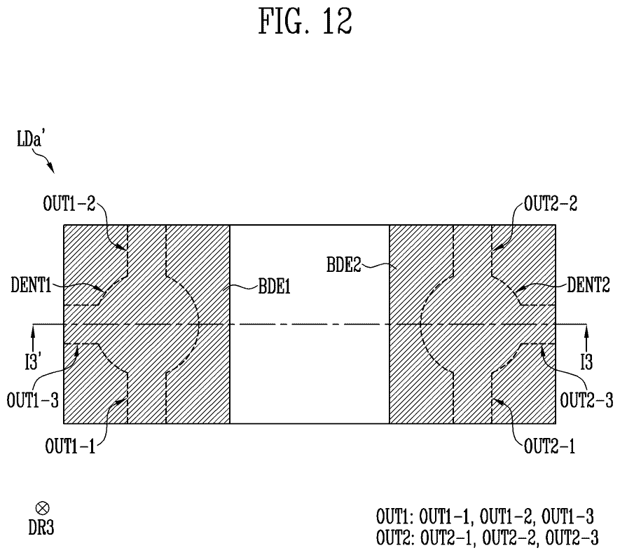

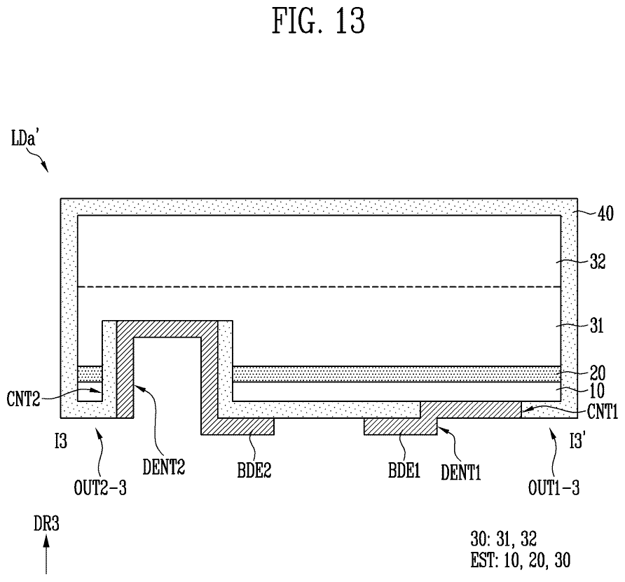

FIG. 12 is a schematic plan view illustrating an embodiment in which the light emitting element shown in FIG. 6 has a plurality of outgassing paths. FIG. 13 is a schematic sectional view taken along line I3-I3′ shown in FIG. 12.

Hereinafter, portions different from those of the embodiment which has been described with reference to FIGS. 6 to 8 will be described, and portions of which description is omitted are the same as (or similar to) the above-described portions.

Referring to FIGS. 12 and 13, a first outgassing path OUT1 may be provided in plurality. For example, the first outgassing path OUT1 may include a (1-1)th outgassing path OUT1-1, a (1-2)th outgassing path OUT1-2, and a (1-3)th outgassing path OUT1-3. However, embodiments are not limited thereto, and the first outgassing path OUT1 may be provided two or four or more.

At least some of the (1-1)th outgassing path OUT1-1, the (1-2)th outgassing path OUT1-2, and the (1-3)th outgassing path OUT1-3 may extend in different directions. For example, as shown in FIG. 12, in plan view, the (1-1)th outgassing path OUT1-1 may extend downwardly from a first indented portion DENT1, the (1-2)th outgassing path OUT1-2 may extend upwardly from the first indented portion DENT1, and the (1-3)th outgassing path OUT1-3 may extend leftwardly from the first indented portion DENT1.

For example, a second outgassing path OUT2 may be provided in plurality. For example, the second outgassing path OUT2 may include a (2-1)th outgassing path OUT2-1, a (2-2)th outgassing path OUT2-2, and a (2-3)th outgassing path OUT2-3. However, embodiments are not limited thereto, and the second outgassing path OUT2 may be provided in two or four or more.

At least some of the (2-1)th outgassing path OUT2-1, the (2-2)th outgassing path OUT2-2, and the (2-3)th outgassing path OUT2-3 may extend in different directions. For example, as shown in FIG. 12, in plan view, the (2-1)th outgassing path OUT2-1 may extend downwardly from a second indented portion DENT2, the (2-2)th outgassing path OUT2-2 may extend upwardly from the second indented portion DENT2, and the (2-3)th outgassing path OUT2-3 may extend rightwardly from the second indented portion DENT2.

As described above, as a light emitting element LDa′ has a plurality of outgassing paths, the bonding reliability of the light emitting element LDa′ may be further improved.

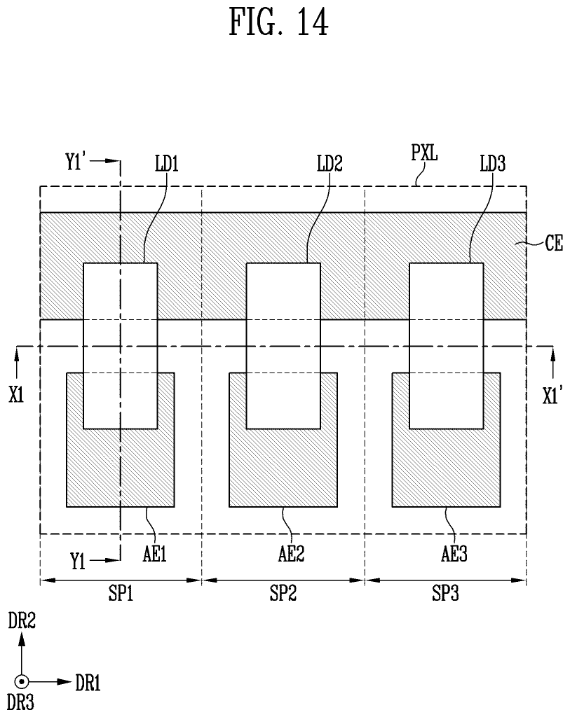

FIG. 14 is a schematic plan view illustrating an embodiment of a pixel to which the light emitting element shown in FIG. 6 is applied.

Referring to FIG. 14, a pixel PXL may include first to third sub-pixels SP1, SP2, and SP3. The first to third sub-pixels SP1, SP2, and SP3 may be arranged in the first direction DR1. However, the arrangement of the pixel PXL is not limited thereto, and may be variously changed in some embodiments. For example, the first to third sub-pixels SP1, SP2, and SP3 may be arranged in a zigzag pattern.

First to third anode electrodes AE1, AE2, and AE3 may be disposed in the first to third sub-pixels SP1, SP2, and SP3, respectively. The first anode electrode AE1 may be provided (or formed) as an anode electrode AE (see FIG. 2) connected to a sub-pixel circuit SPC (see FIG. 2) of the first sub-pixel SP1. The second anode electrode AE2 may be provided (or formed) as an anode electrode AE connected to a sub-pixel circuit SPC of the second sub-pixel SP2. The third anode electrode AE3 may be provided (or formed) as an anode electrode AE connected to a sub-pixel circuit SPC of the third sub-pixel SP3.

A cathode electrode CE may be spaced apart from the first to third anode electrodes AE1, AE2, and AE3. The cathode electrode CE may be disposed at the same height as the first to third anode electrodes AE1, AE2, and AE3. The cathode electrode CE may be spaced apart from the first to third anode electrodes AE1, AE2, and AE3 in the second direction DR2. In embodiments, the cathode electrode CE may extend in the first direction DR1, to be used as a common electrode of the pixel PXL and other pixels adjacent to the pixel PXL. For example, the cathode electrode CE may extend in the second direction DR2 in addition to the first direction DR1, to be used as a common electrode of all the sub-pixels SP shown in FIG. 3. For example, the cathode electrode CE may have various shapes.

First to third light emitting elements LD1, LD2, and LD3 may be disposed on the first to third anode electrodes AE1, AE2, and AE3 and the cathode electrode CE. The first light emitting element LD1 may be connected (e.g., electrically connected) to the first anode electrode AE1 and the cathode electrode CE. The first light emitting element LD1 may be provided (or formed) as a light emitting element LD (see FIG. 2) connected to the sub-pixel circuit SPC of the first sub-pixel SP1. The second light emitting element LD2 may be connected (e.g., electrically connected) to the second anode electrode AE2 and the cathode electrode CE. The second light emitting element LD2 may be provided (or formed) as a light emitting element LD connected to the sub-pixel circuit SPC of the second sub-pixel SP2. The third light emitting element LD3 may be connected (e.g., electrically connected) to the third anode electrode AE3 and the cathode electrode CE. The third light emitting element LD3 may be provided (or formed) as a light emitting element LD connected to the sub-pixel circuit SPC of the third sub-pixel SP3.

The first light emitting element LD1, the second light emitting element LD2, and the third light emitting element LD3 may be formed to be substantially identical (or similar) to any one of the light emitting elements LDa and LDa′ which have been described with reference to FIGS. 6 to 13.

FIG. 15 is a schematic sectional view taken along line Y1-Y1′ shown in FIG. 14.

Referring to FIGS. 14 and 15, a pixel circuit layer PCL, a display panel layer DPL, and a light functional layer LFL may be sequentially disposed on a substrate SUB.

The pixel circuit layer PCL may include insulating layers, semiconductor patterns, and conductive patterns, which are stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1, SP2, and SP3 may include transistors and one or more capacitors. The semiconductor patterns and the conductive patterns of the pixel circuit layer PCL may function as the transistors and the capacitors of the sub-pixel circuit SPC. For example, the conductive patterns of the pixel circuit layer PCL may further function as lines, e.g., the first to m-th gate lines GL1 to GLm, the first to n-th data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused (or permeated) into circuit elements and lines, which are included in the pixel circuit layer PCL. The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided (or formed) as a single layer or a multi-layer. In case that the buffer layer BFL is provided (or formed) as the multi-layer, layers of the multi-layer may be formed of the same material or be formed of different materials.

In embodiments, one or more barrier layers may be disposed between the substrate SUB and the buffer layer BFL. Each of the barrier layers may include polyimide.

A transistor T_SP may be disposed on the buffer layer BFL. The transistor T_SP may be any one of the transistors of the sub-pixel circuit SPC included in the first sub-pixel SP1. For example, the transistor T_SP may be a transistor connected to a first anode electrode AE1 among the transistors of the sub-pixel circuit SPC.

The transistor T_SP may include a semiconductor pattern SCP, a gate electrode GE, a first terminal ET1, and a second terminal ET2. The first terminal ET1 may be any one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the transistor T_SP. The channel region may be a semiconductor pattern substantially undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any one of various types of semiconductors, e.g., any one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride, silicon oxide, silicon oxynitride, and a metal oxide such as aluminum oxide. However, the interlayer insulating layers ILD are not limited thereto. For example, any one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE may be spaced apart from the semiconductor pattern SCP. In embodiments, the gate insulating layer GI may be provided (e.g., entirely provided) on the semiconductor pattern SCP and the buffer layer BFL, to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided (or formed) as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided (or formed) as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

In embodiments, the transistor T_SP may be formed as a low temperature poly-silicon transistor. However, embodiments are not limited thereto. For example, the transistor T_SP may be formed as an oxide semiconductor transistor. In embodiments, the sub-pixel circuit of the first sub-pixel SP1 may include different types of transistors. For example, the transistor T_SP may be formed as a low temperature poly-silicon transistor, and another transistor of the first sub-pixel SP1 may be formed as an oxide semiconductor transistor. An oxide semiconductor of the corresponding oxide semiconductor transistor may be disposed on any one of the interlayer insulating layers ILD instead of an insulating layer on which the semiconductor pattern SCP of the transistor T_SP.

In embodiments, a case where the transistor T_SP is a transistor having a top gate structure is described as an example. However, embodiments are not limited thereto. For example, the transistor T_SP may be a transistor having a bottom gate structure. For example, the structure of the transistor T_SP may be variously changed.

At least a portion of various lines of the display panel DP and/or the display device DD may be further disposed on the interlayer insulating layers ILD.

A first passivation layer PSV1 may be disposed over the interlayer insulating layers ILD and the first and second terminals ET1 and ET2. The passivation layer may function as a protective layer or a via layer. The first passivation layer PSV1 may protect components disposed under the first passivation layer PSV1, and provide a flat top surface (or flat upper surface).

A connection pattern CP may be disposed on the first passivation layer PSV1. The connection pattern CP may be connected to the first terminal ET1 of the transistor T_SP with penetrating the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed over the connection pattern CP and the first passivation layer PSV1. The second passivation layer PSV2 may protect components disposed under the second passivation layer PSV2, and provide a flat top surface (or flat upper surface).

Each of the first and second passivation layers PSV1 and PSV2 may include an inorganic insulating layer including an inorganic material and/or an organic insulating layer including an organic material. The inorganic insulating layer may include, for example, at least one of silicon oxide, silicon nitride, silicon oxynitride, and a metal oxide such as aluminum oxide. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include the same material as any one of the interlayer insulating layers ILD, but embodiments are not limited thereto. Each of the first and second passivation layers PSV1 and PSV2 may be provided (or formed) as a single layer or as a multi-layer.

The display panel layer DPL may be disposed on the second passivation layer PSV2. The display panel layer DPL may include the first anode electrode AE1, a cathode electrode CE, a first bank BNK1, first and second reflective electrodes RFE1 and RFE2, a first light emitting element LD1, an overcoat layer OCL, a third passivation layer PSV3, and a capping layer CPL.

The first anode electrode AE1 and the cathode electrode CE may be disposed on the pixel circuit layer PCL.

The first anode electrode AE1 may be connected (e.g., electrically connected) to the connection pattern CP through a contact hole penetrating the second passivation layer PSV2. For example, the first anode electrode AE1 may be connected (e.g., electrically connected) to the transistor T_SP.

The cathode electrode CE may be spaced apart from the first anode electrode AE1 in the second direction DR2. The cathode electrode CE may be connected (e.g., electrically connected) to the second power voltage node VSSN shown in FIG. 2. Accordingly, the second power voltage applied to the second power voltage node VSSN may be transferred to the cathode electrode CE.

The first bank BNK1 may be disposed on the first anode electrode AE1 and the cathode electrode CE. The first bank BNK1 may have a first opening OP1 exposing portions of the first anode electrode AE1 and the cathode electrode CE. The first light emitting element LD1 may be disposed in the first opening OP1 of the first bank BNK1. For example, the first bank BNK1 may be provided (or formed) as a pixel defining layer defining an area in which the first light emitting element LD1 is positioned.

The first bank BNK1 may include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin.

The first reflective electrode RFE1 may be disposed on the exposed portion of the first anode electrode AE1 and a side surface of the first bank BNK1 which is adjacent to the exposed portion of the first anode electrode AE1. The second reflective electrode RFE2 may be disposed on the exposed portion of the cathode electrode CE and a side surface of the first bank BNK1 which is adjacent to the exposed portion of the cathode electrode CE. The first and second reflective electrodes RFE1 and RFE2 may include conductive materials suitable for reflecting light. Accordingly, the light emission efficiency of the first light emitting element LD1 may be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The first light emitting element LD1 may be formed to be substantially identical (or similar) to any one of the light emitting elements LDa and LDa′ which have been described with reference to FIGS. 6 to 13. Therefore, redundant descriptions will be omitted for descriptive convenience.

A first bonding electrode BDE1 of the first light emitting element LD1 may be connected (e.g., electrically connected) to the first anode electrode AE1 through the first reflective electrode RFE1. A second bonding electrode BDE2 of the first light emitting element LD1 may be connected (e.g., electrically connected) to the cathode electrode CE through the second reflective electrode RFE2. The first light emitting element LD1 may be bonded to the first and second reflective electrodes RFE1 and RFE2. The first light emitting element LD1 may be formed as a flip-chip type light emitting element.

The overcoat layer OCL may be disposed in the first opening OP1 in which the first and second reflective electrodes RFE1 and RFE2 and the first light emitting element LD1 are disposed. The overcoat layer OCL may fix the first light emitting element LD1 bonded to the first and second reflective electrodes RFE1 and RFE2 not to move. For example, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed over the first bank BNK1 and the overcoat layer OCL. The third passivation layer PSV3 may protect components disposed under the third passivation layer PSV3, and provide a flat surface. The third passivation layer PSV3 may include the same material as any one of the first and second passivation layers PSV1 and PSV2, but embodiments are not limited thereto.

In embodiments, the third passivation layer PSV3 may not be disposed on a top surface (or upper surface) of the first light emitting element LD1. The first light emitting element LD1 may protrude to the light functional layer LFL. The first light emitting element LD1 may be at least partially positioned in a second opening OP2 of a second bank BNK2. For example, a height of the top surface of the first light emitting element LD1 from the substrate SUB may be higher than a height of a lowermost end of a reflective layer RFL from the substrate SUB. Accordingly, light emitted from the first light emitting element LD1 may be provided to the light functional layer LFL at a relatively high ratio.

The capping layer CPL may be disposed on the third passivation layer PSV3. The capping layer CPL may protect components disposed under the capping layer CPL, such as the first light emitting element LD1, from external moisture, humidity, and the like. In embodiments, the capping layer CPL may not be disposed on the top surface of the first light emitting element LD1. In other embodiments, the capping layer CPL may cover (e.g., entirely cover) the first light emitting element LD1 and the third passivation layer PSV3. The capping layer CPL may include at least one of silicon nitride, silicon oxide, silicon oxynitride, and a metal oxide such as aluminum oxide. However, the material of the capping layer CPL is not limited thereto.

In the above, the pixel circuit layer PCL and the display panel layer DPL of the first sub-pixel SP1 have been described. Each of the second and third sub-pixels SP2 and SP3 shown in FIG. 14 may also be formed identically or similarly to the first sub-pixel SP1 within a range in which it is not differently described herein.

The light functional layer LFL may be disposed on the capping layer CPL. The light functional layer LFL may include the second bank BNK2, the reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1. The second bank BNK2 may have the second opening OP2 overlapping the first opening OP1.

The second bank BNK2 may include a light blocking material, to prevent light mixture between adjacent sub-pixels. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second opening OP2. The reflective layer RFL may reflect incident light, and accordingly, light emission efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the second opening OP2. The fourth passivation layer PSV4 may protect components disposed under the fourth passivation layer PSV4, and provide a flat surface. The fourth passivation layer PSV4 may include the same material as any one of the first to third passivation layers PSV1, PSV2, and PSV3, but embodiments are not limited thereto.

On the fourth passivation layer PSV4, the first light conversion pattern CCP1 may be disposed in the second opening OP2.

The first light conversion pattern CCP1 may include color conversion particles and/or light scattering particles. The color conversion particles may convert incident light into light of another color by changing a wavelength of the incident light. For example, the color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 that convert light of the blue color into light of a red color. In case that the first light emitting element LD1 emits light of the red color, the first light conversion pattern CCP1 may include light scattering particles. For example, the particles included in the first light conversion pattern CCP1 may be variously changed according to the first light emitting element LD1.

The low refractive layer LRL may be disposed on the second bank BNK2, the reflective layer RFL, and the first light conversion pattern CCP1. The low refractive layer LRL may have a refractive index lower than a refractive index of the first light conversion pattern CCP1. The low refractive layer LRL may refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 may be improved.

The color filter layer CFL may be disposed on the low refractive layer LRL. The color filter layer CFL may include a first color filter CF1 and light blocking patterns LBP. The first color filter CF1 overlaps the first light conversion pattern CCP1. The first color filter CF1 may allow light in a selected wavelength range to be selectively transmitted therethrough. In case that the first sub-pixel SP1 is a red sub-pixel, the first color filter CF1 may include a red color filter. The light blocking patterns LBP may include at least one of various kinds of light blocking materials.

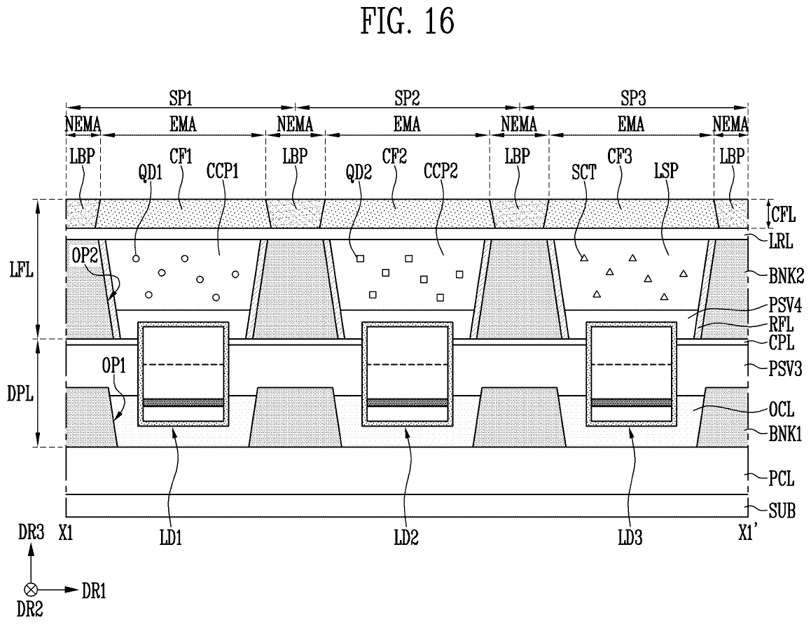

FIG. 16 is a schematic sectional view taken along line X1-X1′ shown in FIG. 14.

Referring to FIGS. 14 and 16, a pixel circuit layer PCL, a display panel layer DPL, and a light functional layer LFL may be provided on a substrate SUB.

The pixel circuit layer PCL and the display panel layer DPL are the same as (or similar to) described with reference to FIG. 15. In the pixel circuit layer PCL, sub-pixel circuits respectively corresponding to the first to third sub-pixels SP1, SP2, and SP3 are provided. In the display panel layer DPL, first to third light emitting elements LD1, LD2, and LD3 respectively corresponding to the first to third sub-pixels SP1, SP2, and SP3 may be provided. The first to third light emitting elements LD1, LD2, and LD3 may overlap first openings OP1 of a first bank BNK1. The first light emitting element LD1 may be connected between a cathode electrode CE (see FIG. 15) and a transistor T_SP (see FIG. 15) included in a sub-pixel circuit of the first sub-pixel SP1. The second light emitting element LD2 may be connected between the cathode electrode CE and a transistor included in a sub-pixel circuit of the second sub-pixel SP2. The third light emitting element LD3 may be connected between the cathode electrode CE and a transistor included in a sub-pixel circuit of the third sub-pixel SP3. Hereinafter, redundant descriptions will be omitted for descriptive convenience.

The light functional layer LFL may be provided on the display panel layer DPL. The light functional layer LFL is the same as (or similar to) described with reference to FIG. 15. Hereinafter, redundant descriptions will be omitted for descriptive convenience.

A second bank BNK2 may have second openings OP2. It may be understood that emission areas EMA and a non-emission area NEMA of the first to third sub-pixels SP1, SP2, and SP3 are defined by the second bank BNK2. An area overlapping the second bank BNK2 may correspond to the non-emission area NEMA. Areas overlapping the second openings OP2 of the second bank BNK2 may correspond to the emission areas EMA of the first to third sub-pixels SP1, SP2, and SP3.

On a capping layer CPL, a fourth passivation layer PSV4 may be disposed in the second openings OP2. On the fourth passivation layer PSV4, first and second light conversion patterns CCP1 and CCP2 and a light scattering pattern LSP may be disposed in the second openings OP2.

In embodiments, the first to third light emitting elements LD1, LD2, and LD3 may emit light of a blue color. The first light conversion pattern CCP1 may include first color conversion particles QD1 that convert light of the blue color into light of a red color. The second light conversion pattern CCP2 may include second color conversion particles QD2 that convert light of the blue color into light of a green color. The light scattering pattern LSP may include light scattering particles SCT which scatter light of the blue color so as to improve light emission efficiency. Accordingly, the first to third sub-pixels SP1, SP2, and SP3 may be provided (or formed) as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

In embodiments, the first to third light emitting elements LD1, LD2, and LD3 may emit lights of the red color, the green color, and the blue color, respectively. Each of the first and second light conversion patterns CCP1 and CCP2 and the light scattering pattern LSP may include the light scattering particles SCT. For example, the particles included in the first and second light conversion patterns CCP1 and CCP2 and the light scattering pattern LSP may be variously changed according to colors of lights emitted from the first to third light emitting elements LD1, LD2, and LD3.

In embodiments, the first and second light conversion patterns CCP1 and CCP2 and the light scattering pattern LSP may be omitted.

A low refractive layer LRL may be disposed on the second bank BNK2, a reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. In embodiments, the low refractive layer LRL may be omitted in an area corresponding to the third sub-pixel SP3.

A color filter layer CFL may be disposed on the low refractive layer LRL. The color filter layer CFL may include the first to third color filters CF1, CF2, and CF3 and light blocking patterns LBP.

Each of the first to third color filters CF1, CF2, and CF3 may selectively transmit light in a selected wavelength range therethrough. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a refractive index higher than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas EMA and the non-emission area NEMA of the first and second sub-pixels SP1, SP2, and SP3 are defined by the light blocking patterns LBP. An area overlapping the light blocking patterns LBP may correspond to the non-emission area NEMA. Areas not overlapping the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlapping each other. In another example, a light blocking pattern between the first and second color filters CF1 and CF2 among the light blocking patterns LBP may be formed as a multi-layer in which the first and second color filters CF1 and CF2 overlap each other, and a light blocking pattern between the second and third color filters CF2 and CF3 among the light blocking patterns LBP may be formed as a multi-layer in which the second and third color filters CF2 and CF3 overlap each other. Alight blocking pattern between the first color filter CF1 and a third color filter CF3 of an adjacent pixel may be formed as a multi-layer in which the first and third color filters CF1 and CF3 overlap each other. For example, each of the first to third color filters CF1, CF2, and CF3 may extend to the non-emission area NEMA to form the light blocking patterns LBP.

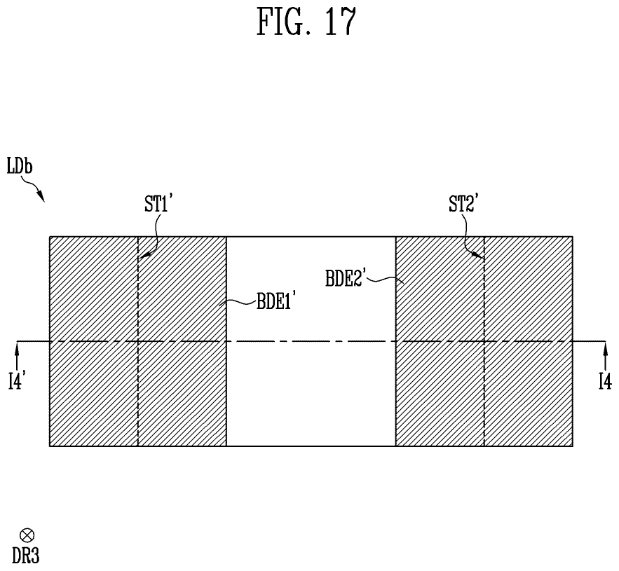

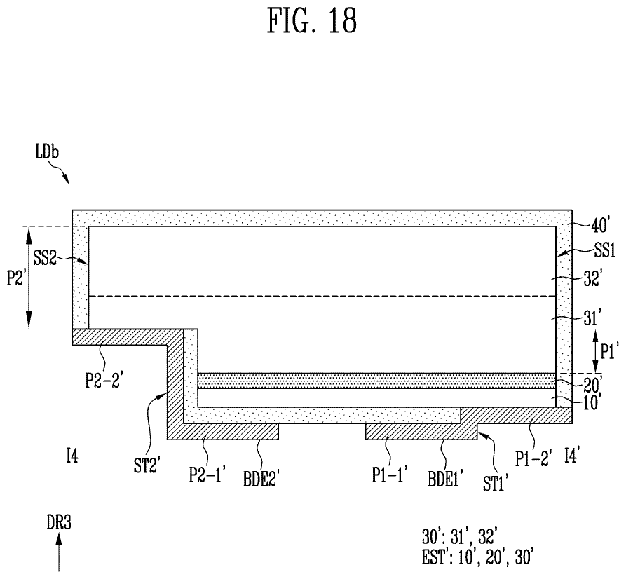

FIG. 17 is a schematic plan view illustrating a second embodiment of the light emitting element included in the sub-pixel shown in FIG. 3. FIG. 18 is a schematic sectional view taken along line I4-I4′ shown in FIG. 17.

Referring to FIGS. 17 and 18, a light emitting element LDb may include a light emitting stack member EST′, a first bonding electrode BDE1′, a second bonding electrode BDE2′, and an insulative film 40′. The light emitting stack member EST′ may include a first semiconductor layer 10′, an active layer 20′, and a second semiconductor layer 30′, which are sequentially stacked in the third direction DR3. The third direction DR3 may be designated as a thickness direction.

The first semiconductor layer 10′ may provide (or include) holes. The first semiconductor layer 10′ may have a first polarity. For example, the first semiconductor layer 10′ may include at least one p-type semiconductor layer. The first semiconductor layer 10′ may be described identically or similarly to the first semiconductor layer 10 (see FIGS. 6 to 8). Hereinafter, redundant descriptions will be omitted for descriptive convenience.

The active layer 20′ may be interposed between the first semiconductor layer 10′ and the second semiconductor layer 30′ to provide an area in which electrons and holes are recombined. The active layer 20′ may be described identically or similarly to the active layer 20 (see FIGS. 6 to 8). Hereinafter, redundant descriptions will be omitted for descriptive convenience.

The second semiconductor layer 30′ may provide electrons. The second semiconductor layer 30′ may have a second polarity different from the first polarity. For example, the second semiconductor layer 30′ may include at least one n-type semiconductor layer. The second semiconductor layer 30′ may be described identically or similarly to the second semiconductor layer 30 (see FIGS. 6 to 8). Hereinafter, redundant descriptions will be omitted for descriptive convenience.

In some embodiments, the second semiconductor layer 30′ may include a first doping portion 31′ disposed on the active layer 20′ and a second doping portion 32′ disposed on the first doping portion 31′. The first doping portion 31′ may be an area in which a dopant is doped at a relatively high concentration. The second doping portion 32′ may be an area in which the dopant is doped at a relatively low concentration or an area in which the dopant is not substantially doped. For example, a first average doping concentration in the first doping portion 31′ may be greater than a second average doping concentration in the second doping portion 32′. The first doping portion 31′ and the second doping portion 32′ may be integral with each other such that the second semiconductor layer 30′ may be formed.

In embodiments, the second semiconductor layer 30′ may include a first portion P1′ and a second portion P2′ on the first portion P1′. The first portion P1′ may substantially overlap the first semiconductor layer 10′ and the active layer 20′ in plan view. That the first portion P1′ substantially overlaps the first semiconductor layer 10′ and the active layer 20′ in plan view may mean that a shape of the first portion P1′ in plan view completely overlaps a shape of the first semiconductor layer 10′ and the active layer 20′ in plan view or that the shape of the first portion P1′ in plan view overlaps about 95% or more of the shape of the first semiconductor layer 10′ and the active layer 20′ in plan view. The second portion P2′ may have an area larger than an area of the first portion P1′ in plan view. The first portion P1′ and the second portion P2′ may be aligned with each other at a side surface SS1 of the light emitting stack member EST′. In another example, the first portion P1′ and the second portion P2′ may not be aligned with each other at an opposite side surface SS2 of the light emitting stack member EST′. For example, in an area adjacent to the opposite side surface SS2 of the light emitting stack member EST′, the second portion P2′ may not overlap the first portion P1′ in plan view. The first portion P1′ and the second portion P2′ may be integral with each other such that the second semiconductor layer 30′ may be formed.

In embodiments, the first portion P1′ may be formed as a portion of the first doping portion 31′ adjacent to the active layer 20′, and the second portion P2′ may be formed as another portion of the first doping portion 31′ and the second doping portion 32′.

The insulative film 40′ may cover at least a portion of an outer circumferential surface of the light emitting stack member EST′. For example, the insulative film 40′ may cover at least a side surface of the active layer 20′. For example, the insulative film 40′ may cover a portion of a bottom surface of the first semiconductor layer 10′. The insulative film 40′ may include a transparent insulative material. The insulative film 40′ may prevent an electrical short circuit which occurs in case that the active layer 20′ is in contact with another component having conductivity. In embodiments, the insulative film 40′ may have a multi-layer including a plurality of layers including a transparent insulative material.

The first bonding electrode BDE1′ may be connected (e.g., electrically connected) to the first semiconductor layer 10′. For example, the first bonding electrode BDE1′ may extend from the insulative film 40′ covering the portion of the bottom surface of the first semiconductor layer 10′ to the side surface SS1 of the light emitting stack member EST′. The bottom surface of the first semiconductor layer 10′, which is adjacent to the side surface SS1 of the light emitting stack member EST′, is not covered by the insulative film 40 but may be exposed. The first bonding electrode BDE1′ may be electrically connected to (or in contact with) the bottom surface of the first semiconductor layer 10′, which is adjacent to the side surface SS1 of the light emitting stack member EST′. The first bonding electrode BDE1′ may include, for example, a eutectic metal.

In embodiments, the first bonding electrode BDE1′ may include a (1-1)th bonding portion P1-1′ overlapping the insulative film 40′ covering the portion of the bottom surface of the first semiconductor layer 10′ and a (1-2)th bonding portion P1-2′ adjacent to the side surface SS1 of the light emitting stack member EST′. The (1-2)th bonding portion P1-2′ may be a portion overlapping another portion of the bottom surface of the first semiconductor layer 10′, which is not covered by the insulative film 40′. The (1-1)th bonding portion P1-1′ and the (1-2)th bonding portion P1-2′ may be integral with each other such that the first bonding electrode BDE1′ may be formed. A first step difference ST1′ may be defined (or formed) in the third direction DR3 between the (1-1)th bonding portion P1-1′ and the (1-2)th bonding portion P1-2′. For example, the (1-2)th bonding portion P1-2′ may be positioned upwardly of the (1-1)th bonding portion P1-1′.

The second bonding electrode BDE2′ may be connected (e.g., electrically connected) to the second semiconductor layer 30′. For example, the second bonding electrode BDE2′ may extend from the insulative film 40 covering the portion of the bottom surface of the first semiconductor layer 10′ to the opposite side surface SS2 of the light emitting stack member EST′. In an area adjacent to the opposite side surface SS2 of the light emitting stack member EST′, a portion of the second portion P2′ may be exposed and may not overlap the first portion P1′. The second bonding electrode BDE2′ may be electrically connected to (or in contact with) the exposed portion of the second portion P2′, which is adjacent to the opposite side surface SS2 of the light emitting stack member EST′. The second bonding electrode BDE2′ may include, for example, a eutectic metal.

In embodiments, the second bonding electrode BDE2′ may include a (2-1)th bonding portion P2-1′ overlapping the insulative film covering the portion of the bottom surface of the first semiconductor layer 10′ and a (2-2)th bonding portion P2-2′ adjacent to the opposite side surface SS2 of the light emitting stack member EST′. The (2-2)th bonding portion P2-2′ may be a portion electrically connected to (or in contact with) the second portion P2′ not overlapping the first portion P1′ under the second portion P2′. The (2-1)th bonding portion P2-1′ and the (2-2)th bonding portion P2-2′ may be integral with each other such that the second bonding electrode BDE2′ may be formed. A second step difference ST2′ may be defined (or formed) in the third direction DR3 between the (2-1)th bonding portion P2-1′ and the (2-2)th bonding portion P2-2′. For example, the (2-2)th bonding portion P2-2′ may be positioned upwardly of the (2-1)th bonding portion P2-1′. The second step difference ST2′ may be larger than the first step difference ST1′.

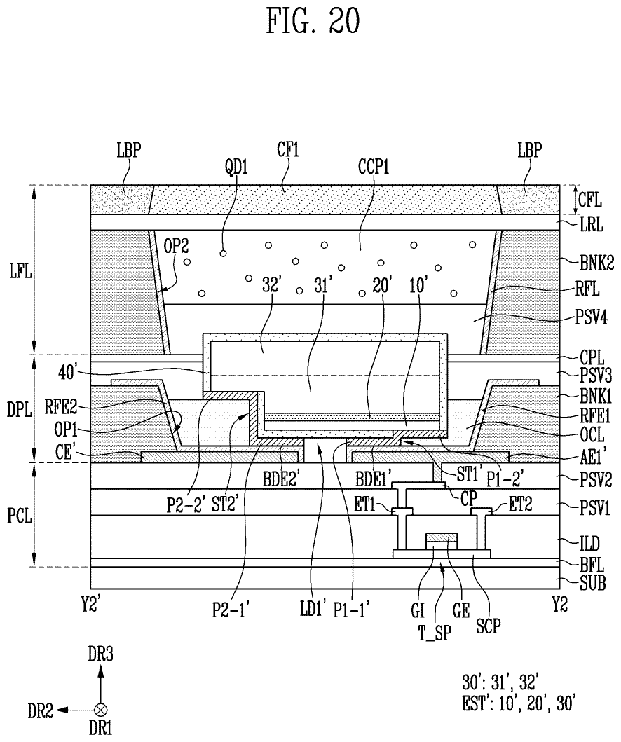

The (1-1)th bonding portion P1-1′ of the first bonding electrode BDE1′ may be portion bonded to an electrode (e.g., RFE1 shown in FIG. 20). Since the first bonding electrode BDE1′ has the first step difference ST1′, any closed space may not be substantially defined (or formed) between the first bonding electrode BDE1′ and the electrode (e.g., RFE1 shown in FIG. 20) disposed thereunder. For example, the (2-1)th bonding portion P2-1′ of the second bonding electrode BDE2′ may be a portion bonded to an electrode (e.g., RFE2 shown in FIG. 20). Since the second bonding electrode BDE2′ has the second step difference ST2′, any closed space may not be substantially defined (or formed) between the second bonding electrode BDE2′ and the electrode (RFE2 shown in FIG. 20) disposed thereunder. Thus, the bonding reliability of the light emitting element LDb may be improved.

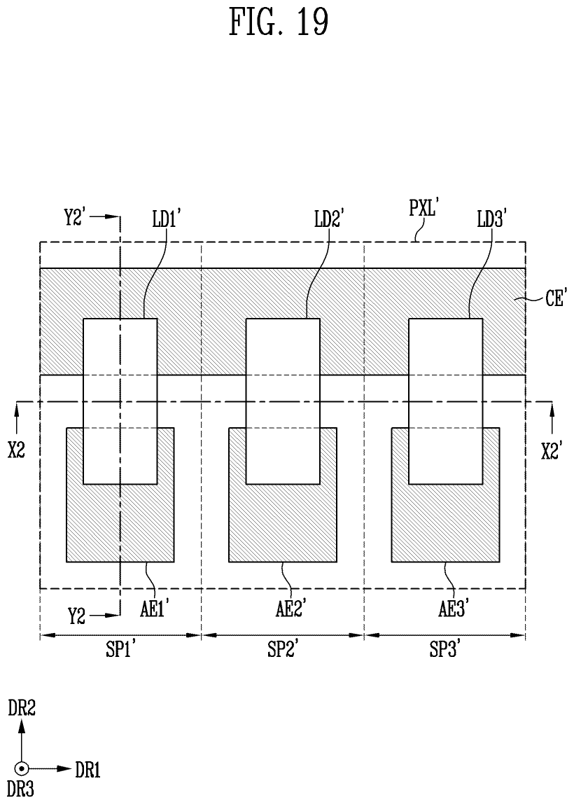

FIG. 19 is a schematic plan view illustrating an embodiment of a pixel to which the light emitting element shown in FIG. 17 is applied.

Referring to FIG. 19, a pixel PXL′ may include first to third sub-pixels SP1′, SP2′, and SP3′. First to third anode electrodes AE1′, AE2′, and AE3′ may be disposed in the first to third sub-pixels SP1′, SP2′, and SP3′, respectively. A cathode electrode CE′ may be spaced apart from the first to third anode electrodes AE1′, AE2′, and AE3′.

The pixel PXL′ and the components SP1′, SP2′, SP3′, AE1′, AE2′, AE3′, and CE′ may be described identically or similarly to the pixel PXL and the components SP1, SP2, SP3, AE1, AE2, AE3, and CE included on the pixel PXL, which have been described with reference to FIG. 14. Therefore, redundant descriptions will be omitted for descriptive convenience.

First to third light emitting elements LD1′, LD2′, and LD3′ may be disposed on the first to third anode electrodes AE1′, AE2′, and AE3′ and the cathode electrode CE′. The first light emitting element LD1′ may be connected (e.g., electrically connected) to the first anode electrode AE1′ and the cathode electrode CE′. The first light emitting element LD1′ may be provided (or formed) as alight emitting element LD (see FIG. 2) connected to a sub-pixel circuit SPC (see FIG. 2) of the first sub-pixel SP1′. The second light emitting element LD2′ may be connected (e.g., electrically connected) to the second anode electrode AE2′ and the cathode electrode CE′. The second light emitting element LD2′ may be provided (or formed) as a light emitting element LD connected to a sub-pixel circuit SPC of the second sub-pixel SP2′. The third light emitting element LD3′ may be connected (e.g., electrically connected) to the third anode electrode AE3′ and the cathode electrode CE′. The third light emitting element LD3′ may be provided (or formed) as a light emitting element LD connected to a sub-pixel circuit SPC of the third sub-pixel SP3′.

The first light emitting element LD1′, the second light emitting element LD2′, and the third light emitting element LD3′ may be formed to be substantially identical (or similar) to the light emitting element LDb which has been described with reference to FIGS. 17 and 18.

FIG. 20 is a schematic sectional view taken along line Y2-Y2′ shown in FIG. 19.

Referring to FIGS. 19 and 20, a pixel circuit layer PCL, a display panel layer DPL, and a light functional layer LFL may be sequentially disposed on a substrate SUB.

The pixel circuit layer PCL is the same as (or similar to) has been described with reference to FIG. 15. Therefore, redundant descriptions will be omitted for descriptive convenience.

The display panel layer DPL may be disposed on the pixel circuit layer PCL. The display panel layer DPL may include a first anode electrode AE1′, a cathode electrode CE′, a first bank BNK1, first and second reflective electrodes RFE1 and RFE2, a first light emitting element LD1′, an overcoat layer OCL, a third passivation layer PSV3, and a capping layer CPL.

The first anode electrode AE1′ and the cathode electrode CE′ may be disposed on the pixel circuit layer PCL. The first anode electrode AE1′ and the cathode electrode CE′ are described identically or similarly to the first anode electrode AE1 and the cathode electrode CE, which have been described with reference to FIG. 15. Therefore, redundant descriptions will be omitted for descriptive convenience.

The first bank BNK1 may be disposed on the first anode electrode AE1′ and the cathode electrode CE′. The first bank BNK1 may have a first opening OP1 exposing portions of the first anode electrode AE1′ and the cathode electrode CE′. The first reflective electrode RFE1 may be disposed on the exposed portion of the first anode electrode AE1′ and a side surface of the first bank BNK1 which is adjacent to the exposed portion of the first anode electrode AE1′. The second reflective electrode RFE2 may be disposed on the exposed portion of the cathode electrode CE′ and a side surface of the first bank BNK1 which is adjacent to the exposed portion of the cathode electrode CE′.

The first bank BNK1, the first reflective electrode RFE1, and the second reflective electrode RFE2 are the same as (or similar to) described with reference to FIG. 15. Therefore, redundant descriptions will be omitted for descriptive convenience.

The first light emitting element LD1′ may be formed identically or similarly to the light emitting element LDb which has been described with reference to FIGS. 18 and 19. Therefore, redundant descriptions will be omitted for descriptive convenience.

A first bonding electrode BDE1′ of the first light emitting element LD1′ may be connected (e.g., electrically connected) to the first anode electrode AE1′ through the first reflective electrode RFE1. For example, a (1-1)th bonding portion P1-1′ of the first bonding electrode BDE1′ may be bonded to the first reflective electrode RFE1. A second bonding electrode BDE2′ of the first light emitting element LD1′ may be connected (e.g., electrically connected) to the cathode electrode CE′ through the second reflective electrode RFE2. For example, a (2-1)th bonding portion P2-1′ of the second bonding electrode BDE2′ may be bonded to the second reflective electrode RFE2. For example, the first light emitting element LD1′ may be bonded to the first and second reflective electrodes RFE1 and RFE2. The first light emitting element LD1′ may be formed as a flip-chip type light emitting element.

The overcoat layer OCL may be disposed in the first opening OP1 in which the first and second reflective electrodes RFE1 and RFE2 and the first light emitting element LD1′ are disposed. The third passivation layer PSV3 may be disposed over the first bank BNK1 and the overcoat layer OCL. The capping layer CPL may be disposed on the third passivation layer PSV3.

The overcoat layer OCL, the third passivation layer PSV3, and the capping layer CPL are the same as (or similar to) described with reference to FIG. 15. Therefore, redundant descriptions will be omitted for descriptive convenience.

In the above, the pixel circuit layer PCL and the display panel layer DPL of the first sub-pixel SP1′ have been described. Each of the second and third sub-pixels SP2′ and SP3′ shown in FIG. 19 may also be formed identically or similarly to the first sub-pixel SP1′ within a range in which it is not differently described herein.

The light functional layer LFL may be disposed on the capping layer CPL. The light functional layer LFL is the same as (or similar to) described with reference to FIG. 15. Therefore, redundant descriptions will be omitted for descriptive convenience.

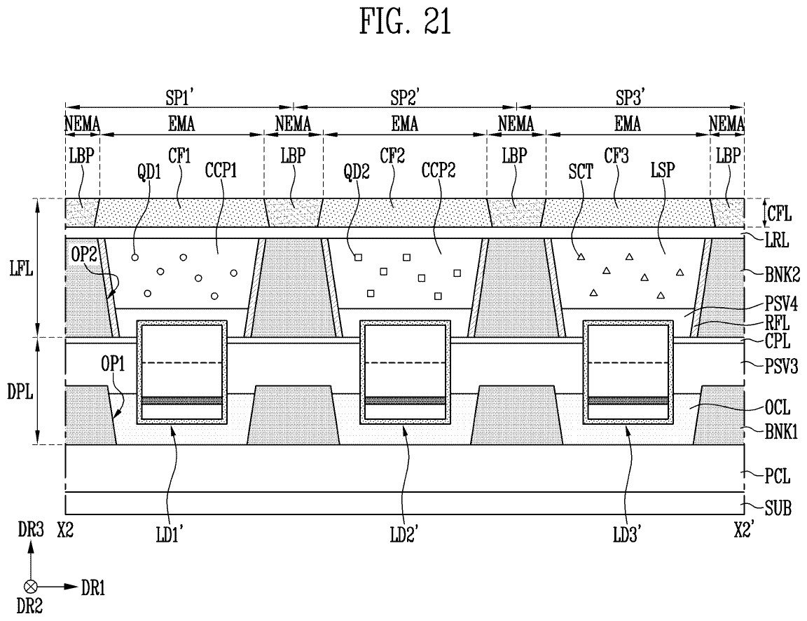

FIG. 21 is a schematic sectional view taken along line X2-X2′ shown in FIG. 19.

Referring to FIGS. 19 and 21, a pixel circuit layer PCL, a display panel layer DPL, and a light functional layer LFL may be provided on a substrate SUB.

The pixel circuit layer PCL and the display panel layer DPL are the same as (or similar to) described with reference to FIG. 20. In the pixel circuit layer PCL, sub-pixel circuits respectively corresponding to the first to third sub-pixels SP1′, SP2′, and SP3′ are provided. In the display panel layer DPL, first to third light emitting elements LD1′, LD2′, and LD3′ respectively corresponding to the first to third sub-pixels SP1′, SP2′, and SP3′ may be provided. The first to third light emitting elements LD1′, LD2′, and LD3′ may overlap first openings OP1 of a first bank BNK1. The first light emitting element LD1′ may be connected between a cathode electrode CE′ (see FIG. 20) and a transistor T_SP (see FIG. 20) included in a sub-pixel circuit of the first sub-pixel SP1′. The second light emitting element LD2′ may be connected between the cathode electrode CE′ and a transistor included in a sub-pixel circuit of the second sub-pixel SP2′. The third light emitting element LD3′ may be connected between the cathode electrode CE′ and a transistor included in a sub-pixel circuit of the third sub-pixel SP3′. Hereinafter, redundant descriptions will be omitted for descriptive convenience.

The light functional layer LFL may be provided on the display panel layer DPL. The light functional layer LFL is the same as (or similar to) described with reference to FIG. 16. Hereinafter, redundant descriptions will be omitted for descriptive convenience.

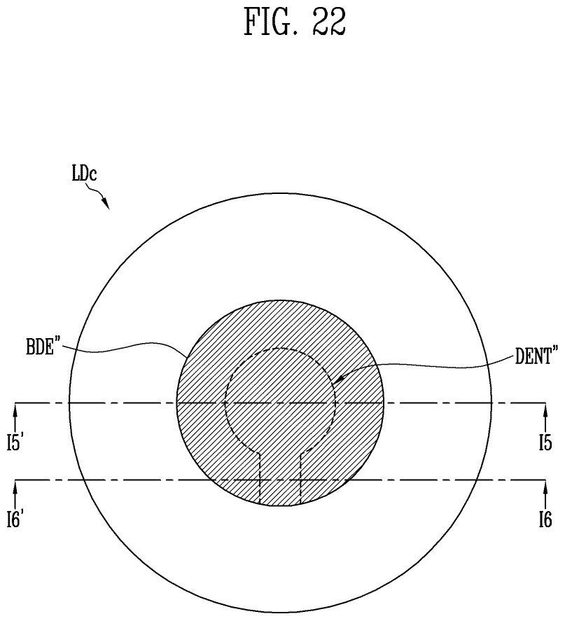

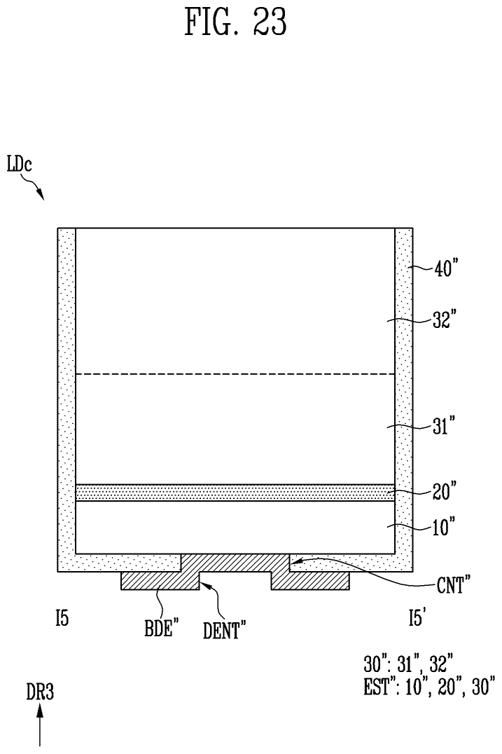

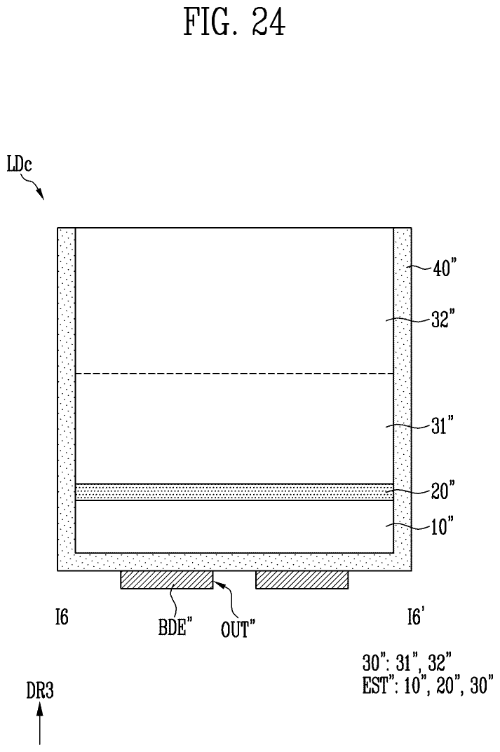

FIG. 22 is a schematic plan view illustrating a third embodiment of the light emitting element included in the sub-pixel shown in FIG. 3. FIG. 23 is a schematic sectional view taken along line I5-I5′ shown in FIG. 22. FIG. 24 is a schematic sectional view taken along line I6-I6′ shown in FIG. 22.

Referring to FIGS. 22 to 24, alight emitting element LDc may include alight emitting stack member EST″, a bonding electrode BDE″, and an insulative film 40″. The light emitting stack member EST″ may include a first semiconductor layer 10″, an active layer 20″, and a second semiconductor layer 30″, which are sequentially stacked in the third direction DR3. The third direction DR3 may be designated as a thickness direction.

The first semiconductor layer 10″ may provide (or include) holes. The first semiconductor layer 10″ may have a first polarity. For example, the first semiconductor layer 10″ may include at least one p-type semiconductor layer. The first semiconductor layer 10″ may be described identically or similarly to the first semiconductor layer 10 (see FIGS. 6 to 8). Hereinafter, redundant descriptions will be omitted for descriptive convenience.

The active layer 20″ may be interposed between the first semiconductor layer 10″ and the second semiconductor layer 30″ to provide an area in which electrons and holes are recombined. The active layer 20″ may be described identically or similarly to the active layer 20 (see FIGS. 6 to 8). Hereinafter, redundant descriptions will be omitted for descriptive convenience.

The second semiconductor layer 30″ may provide electrons. The second semiconductor layer 30″ may have a second polarity different from the first polarity. For example, the second semiconductor layer 30″ may include at least one n-type semiconductor layer. The second semiconductor layer 30″ may be described identically or similarly to the second semiconductor layer 30 (see FIGS. 6 to 8). Hereinafter, redundant descriptions will be omitted for descriptive convenience.

In some embodiments, the second semiconductor layer 30″ may include a first doping portion 31″ disposed on the active layer 20″ and a second doping portion 32″ disposed on the first doping portion 31″. The first doping portion 31″ may be an area in which a dopant is doped at a relatively high concentration. The second doping portion 32″ may be an area in which the dopant is doped at a relatively low concentration or an area in which the dopant is not substantially doped. For example, a first average doping concentration in the first doping portion 31″ may be greater than a second average doping concentration in the second doping portion 32″. The first doping portion 31″ and the second doping portion 32″ may be integral with each other such that the second semiconductor layer 30″ may be formed.

In embodiments, the light emitting stack member EST″ may have a pillar shape. For example, the light emitting stack member EST″ may have a circular pillar shape. Side surfaces of the first semiconductor layer 10″, the active layer 20″, and the second semiconductor layer 30″ may be aligned with each other.

The insulative film 40″ may cover at least a portion of an outer circumferential surface of the light emitting stack member EST″. For example, the insulative film 40″ may cover at least the side surface of the active layer 20″. For example, the insulative film 40″ may expose a top surface (or upper surface) of the light emitting stack member EST″. The insulative film 40″ may include a transparent insulative material. The insulative film 40″ may prevent an electrical short circuit which occurs in case that the active layer 20″ is in contact with another component having conductivity. In embodiments, the insulative film 40″ may have a multi-layer member including a plurality of layers including a transparent insulative material.

The bonding electrode BDE″ may be disposed under the first semiconductor layer 10″. The bonding electrode BDE″ may be connected (e.g., electrically connected) to the first semiconductor layer 10″. The bonding electrode BDE″ may include, for example, a eutectic metal.

In embodiments, the insulative film 40″ may define (or include) a penetration hole CNT″ exposing a portion of a bottom surface of the first semiconductor layer 10″. The bonding electrode BDE″ may be connected (e.g., electrically connected) to the first semiconductor layer 10″ through the penetration hole CNT″.

In embodiments, the bonding electrode BDE″ may define (or include) an indented portion DENT″ indented in the third direction DR3. The indented portion DENT″ may overlap the penetration hole CNT″. In an area in which the indented portion DENT″ is defined (or formed), the bonding electrode BDE″ may be connected (e.g., electrically connected) to the first semiconductor layer 10″. For example, as shown in FIG. 23, the bonding electrode BDE″ may be in contact with (e.g., electrically connected to) the first semiconductor layer 10″ in the area in which the indented portion DENT″ is defined (or formed).

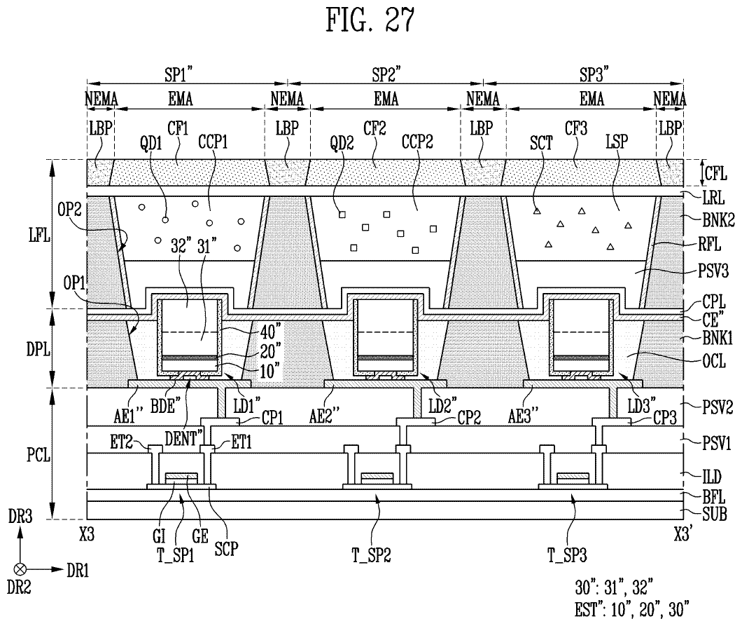

The bonding electrode BDE″ may be bonded on an electrode (e.g., AE1″, AE2″ or AE3″, shown in FIG. 27) connected to a sub-pixel circuit SPC (see FIG. 2) of the display device DD, which will be described later.

A closed space including the indented portion DENT″ may be defined (or formed) between the bonding electrode BDE″ and the electrode (e.g., AE1″, AE2″ or AE3″, shown in FIG. 27) provided under the bonding electrode BDE″. Air existing in the closed space may cause deterioration of the bonding reliability of the light emitting element LDc.

In order to prevent the deterioration, in the disclosure, the bonding electrode BDE″ may define (or include) an outgassing path OUT″ indented in the third direction DR3. For example, in an area in which the outgassing path OUT″ is defined (or formed), the bonding electrode BDE″ may expose the insulative film 40″ covering the bottom surface of the first semiconductor layer 10″. In accordance with embodiments, the insulative film 40″ may be further removed in the area in which the outgassing path OUT″ is defined (or formed). For example, in the area in which the outgassing path OUT″ is defined (or formed), the first semiconductor layer 10″ may be exposed. The outgassing path OUT″ may extend from the indented portion DENT″ to a side surface of the bonding electrode BDE″. Accordingly, air existing in a space defined (or formed) between the bonding electrode BDE″ and the electrode (e.g., AE1″, AE2″ or AE3″, shown in FIG. 27) provided under the bonding electrode BDE″ may be exhausted to the outside through the outgassing path OUT″. Thus, the bonding reliability of the light emitting element LDc may be improved.

In accordance with embodiments, a reflective electrode (or auxiliary electrode) may be further disposed between the bonding electrode BDE″ and the first semiconductor layer 10″. The light emission efficiency of light emitted from the light emitting element LDc may be further improved. The reflective electrode may include a conductive material having a selected reflectivity. The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of the reflective electrode is not limited thereto.

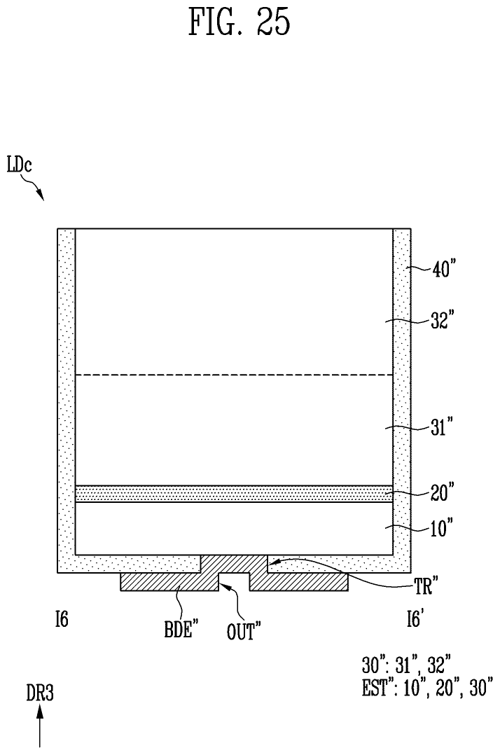

FIG. 25 is a schematic sectional view taken along the line I6-I6′ shown in FIG. 22. FIG. 25 is a schematic sectional view illustrating a modified embodiment of the outgassing path which has described with reference to FIGS. 22 and 24.

Hereinafter, portions different from those of the embodiment which has been described with reference to FIGS. 22 to 24 will be described, and portions of which description is omitted are the same as (or similar to) the above-described portions.

Referring to FIG. 25, the insulative film 40″ may define (or include) a trench TR″ exposing a portion of the bottom surface of the first semiconductor layer 10″. In embodiments, the trench TR″ may be integral with the penetration hole CNT″.

The bonding electrode BDE″ may define (or include) an outgassing path OUT″ indented in the third direction DR3 in an area in which the bonding electrode BDE″ overlaps the trench TR″. In the area in which the outgassing path OUT″ is defined (or formed), the bonding electrode BDE″ may be electrically connected to (or in contact with) the first semiconductor layer 10″ exposed by the trench TR″. The outgassing path OUT″ may extend from the indented portion DENT″ to the side surface of the bonding electrode BDE″. For example, the outgassing path OUT″ may have various shapes in which air existing a space surrounded by the indented portion DENT″ and the electrode (e.g., AE1″, AE2″ or AE3″, shown in FIG. 27) may be exhausted.

Although only an embodiment in which one outgassing path OUT″ is defined (or formed) in the bonding electrode BDE″ is illustrated in FIGS. 22 to 25, embodiments are not limited thereto. For example, similar to as described with reference to FIG. 12, a plurality of outgassing paths OUT″ may be defined (or formed) in the bonding electrode BDE″.

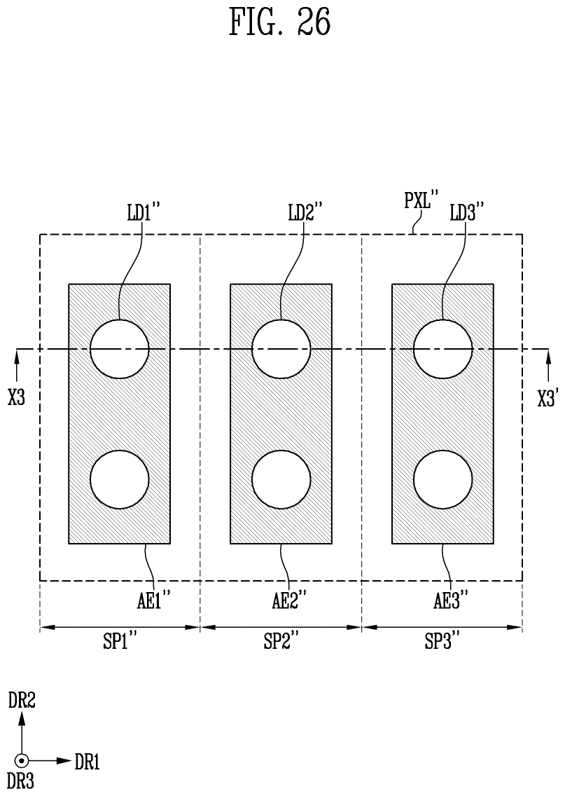

FIG. 26 is a schematic plan view illustrating an embodiment of a pixel to which the light emitting element shown in FIG. 22 is applied.

Referring to FIG. 26, a pixel PXL″ may include first to third sub-pixels SP1″, SP2″, and SP3″. The first to third sub-pixels SP1″, SP2″, and SP3″ may be arranged in the first direction DR1. However, the arrangement of the pixel PXL″ is not limited thereto, and may be variously changed in some embodiments. For example, the first to third sub-pixels SP1″, SP2″, and SP3″ may be arranged in a zigzag pattern.

First to third anode electrodes AE1″, AE2″, and AE3″ may be disposed in the first to third sub-pixels SP1″, SP2″, and SP3″, respectively. The first anode electrode AE1″ may be provided (or formed) as an anode electrode AE included in a sub-pixel circuit SPC (see FIG. 2) of the first sub-pixel SP1″. The second anode electrode AE2″ may be provided (or formed) as an anode electrode AE included in a sub-pixel circuit SPC of the second sub-pixel SP2″. The third anode electrode AE3″ may be provided (or formed) as an anode electrode AE included in a sub-pixel circuit SPC of the third sub-pixel SP3″.

One or more first light emitting elements LD1″, one or more second light emitting elements LD2″, and one or more third light emitting elements LD3″ may be disposed on the first to third anode electrodes AE1″, AE2″, and AE3″, respectively. The first light emitting elements LD1″ may be connected to the first anode electrode AE1″. The second light emitting elements LD2″ may be connected to the second anode electrode AE2″. The third light emitting elements LD3″ may be connected to the third anode electrode AE3″. In case that a plurality of light emitting elements are provided in each sub-pixel, each anode electrode may have a shape extending in a specific direction such as the second direction DR2, and light emitting elements connected to the corresponding anode electrode may be arranged in the same direction.

The first light emitting elements LD1″ may be provided (or formed) as a light emitting element LD (see FIG. 2) included in the first sub-pixel SP1″. The second light emitting elements LD2″ may be provided (or formed) as a light emitting element LD (see FIG. 2) included in the second sub-pixel SP2″. The third light emitting elements LD3″ may be provided (or formed) as a light emitting element LD (see FIG. 2) included in the third sub-pixel SP3″. In case that a plurality of light emitting elements are provided in one sub-pixel, the plurality of light emitting elements may be connected in parallel between an anode electrode and a cathode electrode to be provided (or formed) as the light emitting element LD shown in FIG. 2.

Each of the first light emitting elements LD1″, the second light emitting elements LD2″, and the third light emitting elements LD3″ may be the light emitting element LDc which has been described with reference to FIGS. 22 and 25.

FIG. 27 is a schematic sectional view taken along line X3-X3′ shown in FIG. 26.

Referring to FIGS. 26 and 27, a pixel circuit layer PCL, a display panel layer DPL, and a light functional layer LFL may be sequentially disposed on a substrate SUB.

The pixel circuit layer PCL may include insulating layers, semiconductor patterns, and conductive patterns, which are stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1″, SP2″, and SP3″ may include transistors and one or more capacitors. The semiconductor patterns and the conductive patterns of the pixel circuit layer PCL may function as the transistors and the capacitors of the sub-pixel circuit SPC. For example, the conductive patterns of the pixel circuit layer PCL may further function as lines, e.g., the first to m-th gate lines GL1 to GLm, the first to n-th data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused (or permeated) into circuit elements and lines, which are included in the pixel circuit layer PCL. The buffer layer BFL may include an inorganic insulating layer including an inorganic material. In embodiments, the buffer layer BFL may include at least one of silicon nitride, silicon oxide, silicon oxynitride, and a metal oxide such as aluminum oxide. The buffer layer BFL may be provided (or formed) as a single layer or a multi-layer. In case that the buffer layer BFL is provided (or formed) as the multi-layer, layers of the multi-layer may be formed of the same material or be formed of different materials.

In embodiments, one or more barrier layers may be disposed between the substrate SUB and the buffer layer BFL. Each of the barrier layers may include polyimide.

First to third transistors T_SP1, T_SP2, and T_SP3 respectively corresponding to the first to third sub-pixels SP1″, SP2″, and SP3″ may be disposed on the buffer layer BFL. The first transistor T_SP1 may be any one of transistors of a sub-pixel circuit SPC included in the first sub-pixel SP1″. The second transistor T_SP2 may be any one of transistors of a sub-pixel circuit SPC included in the second sub-pixel SP2″. The third transistor T_SP3 may be any one of transistors of a sub-pixel circuit SPC included in the third sub-pixel SP3″. Each of the first to third transistors T_SP1, T_SP2, and T_SP3 may be understood as a transistor connected to an anode electrode among transistors of a corresponding sub-pixel.

The first transistor T_SP1 may include a semiconductor pattern SCP, a gate electrode GE, a first terminal ET1, and a second terminal ET2. The first terminal ET1 may be any one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the first transistor T_SP1. The channel region may be a semiconductor pattern substantially undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any one of various types of semiconductors, e.g., any one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride, silicon oxide, silicon oxynitride, and a metal oxide such as aluminum oxide. However, the interlayer insulating layers ILD are not limited thereto. For example, any one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE may be spaced apart from the semiconductor pattern SCP. In embodiments, the gate insulating layer GI may be provided (e.g., entirely provided) on the semiconductor pattern SCP and the buffer layer BFL, to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided (or formed) as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided (or formed) as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are illustrated as separate electrodes connected (e.g., electrically connected) to the semiconductor pattern SCP, embodiments are not limited thereto. In embodiments, the first terminal ET1 may be the first contact region adjacent to a side of the channel region of the semiconductor pattern SCP, and the second terminal ET2 may be the second contact region adjacent to the other side of the channel region of the semiconductor pattern SCP. The first terminal ET1 may be connected (e.g., electrically connected) to the first light emitting element LD1″ through a connection means such as a bridge electrode disposed on at least one of the interlayer insulating layers ILD.

In embodiments, the first transistor T_SP1 may be formed as a low temperature poly-silicon transistor. However, embodiments are not limited thereto. For example, the first transistor T_SP1 may be formed as an oxide semiconductor transistor. In embodiments, the sub-pixel circuit of the first sub-pixel SP1″ may include different types of transistors. For example, the first transistor T_SP1 may be formed as a low temperature poly-silicon transistor, and another transistor of the first sub-pixel SP1″ may be formed as an oxide semiconductor transistor. An oxide semiconductor of the corresponding oxide semiconductor transistor may be disposed on any one of the interlayer insulating layers ILD instead of an insulating layer on which the semiconductor pattern SCP of the first transistor T_SP1.

In embodiments, a case where the first transistor T_SP1 is a transistor having a top gate structure is described as an example. However, embodiments are not limited thereto. For example, the first transistor T_SP1 may be a transistor having a bottom gate structure. For example, the structure of the first transistor T_SP1 may be variously changed.

Each of the second and third transistors T_SP2 and T_SP3 may be formed identically or similarly to the first transistor T_SP1. Therefore, descriptions of overlapping portions will be omitted for descriptive convenience.

At least a portion of various lines of the display panel DP and/or the display device DD may be further disposed on the interlayer insulating layers ILD.

A first passivation layer PSV1 may be disposed over the interlayer insulating layers ILD and the first and second terminals ET1 and ET2. The passivation layer may function as a protective layer or a via layer. The first passivation layer PSV1 may protect components disposed under the first passivation layer PSV1, and provide a flat top surface (or flat upper surface).

First to third connection patterns CP1, CP2, and CP3 may be disposed on the first passivation layer PSV1. The first to third connection patterns CP1, CP2, and CP3 may be respectively connected to first terminals ET1 of the first to third transistors T_SP1, T_SP2, and T_SP3 with penetrating the first passivation layer PSV1. The first to third connection patterns CP1, CP2, and CP3 may include at least one material among copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed over the first to third connection patterns CP1, CP2, and CP3 and the first passivation layer PSV1. The second passivation layer PSV2 may protect components disposed under the second passivation layer PSV2, and provide a flat top surface (or flat upper surface).

Each of the first and second passivation layers PSV1 and PSV2 may include an inorganic insulating layer including an inorganic material and/or an organic insulating layer including an organic material. The inorganic insulating layer may include, for example, at least one of silicon oxide, silicon nitride, silicon oxynitride, and a metal oxide such as aluminum oxide. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include the same material as any one of the interlayer insulating layers ILD, but embodiments are not limited thereto. Each of the first and second passivation layers PSV1 and PSV2 may be provided (or formed) as a single layer or as a multi-layer.

The display panel layer DPL may be disposed on the second passivation layer PSV2. The display panel layer DPL may include first to third anode electrodes AE1″, AE2″, and AE3″, a first bank BNK1, first to third light emitting elements LD1″, LD2″, and LD3″, an overcoat layer OCL, a cathode electrode CE″, and a capping layer CPL.

On the pixel circuit layer PCL, the first to third anode electrodes AE1″, AE2″, and AE3″ may be disposed in the first to third sub-pixels SP1″, SP2″, and SP3″, respectively.

The first anode electrode AE1″ may be connected (e.g., electrically connected) to the first connection pattern CP1 through a contact hole penetrating the second passivation layer PSV2. The second anode electrode AE2″ may be connected (e.g., electrically connected) to the second connection pattern CP2 through another contact hole penetrating the second passivation layer PSV2. The third anode electrode AE3″ may be connected (e.g., electrically connected) to the third connection pattern CP3 through still another contact hole penetrating the second passivation layer PSV2. For example, the first to third anode electrodes AE1″, AE2″, and AE3″ may be connected (e.g., electrically connected) to the first to third transistors T_SP1, T_SP2, and T_SP3, respectively.

The first bank BNK1 may be disposed on the first to third anode electrodes AE1″, AE2″, and AE3″. The first bank BNK1 may have first openings OP1 exposing portions of the first to third anode electrodes AE1″, AE2″, and AE3″. The first to third light emitting elements LD1″, LD2″, and LD3″ may be disposed in the first openings OP1 of the first bank BNK1. For example, the first bank BNK1 may be provided (or formed) as a pixel defining layer defining areas in which the first to third light emitting elements LD1″, LD2″, and LD3″ are positioned.

The first bank BNK1 may include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin. In accordance with embodiments, in order to further improve light emission efficiency, a reflective layer including a reflective material may be further disposed on side surfaces of the first bank BNK1, which are adjacent to the first openings OP1.

The first to third light emitting elements LD1″, LD2″, and LD3″ may be disposed on the first to third anode electrodes AE1″, AE2″, and AE3″, respectively. The first to third light emitting elements LD1″, LD2″, and LD3″ may be bonded to the first to third anode electrodes AE1″, AE2″, and AE3″, respectively. Each of the first to third light emitting elements LD1″, LD2″, and LD3″ may be formed to be substantially identical (or similar) to the light emitting element LDc which has been described with reference to FIGS. 22 to 25. Therefore, descriptions of overlapping portions will be omitted for descriptive convenience.

A bonding electrode BDE″ of the first light emitting element LD1″ may be connected to the first anode electrode AE1″. A bonding electrode BDE″ of the second light emitting element LD2″ may be connected to the second anode electrode AE2″. A bonding electrode BDE″ of the third light emitting element LD3″ may be connected to the third anode electrode AE3″. Top surfaces (or upper surfaces) of second semiconductor layers 30″ of the first to third light emitting elements LD1″, LD2″, and LD3″ may be connected to the cathode electrode CE″. Accordingly, the first light emitting element LD1″ may be connected between the first anode electrode AE1″ and the cathode electrode CE″, the second light emitting element LD2″ may be connected between the second anode electrode AE2″ and the cathode electrode CE″, and the third light emitting element LD3″ may be connected between the third anode electrode AE3″ and the cathode electrode CE″.

The overcoat layer OCL may be disposed in the first openings OP1 in which the first to third light emitting elements LD1″, LD2″, and LD3″ are disposed. The overcoat layer OCL may fix the first to third light emitting elements LD1″, LD2″, and LD3″ bonded to the first to third anode electrodes AE1″, AE2″, and AE3″ not to move. For example, the overcoat layer OCL may protect components disposed under the overcoat layer OCL from a foreign matter such as dust or moisture. The overcoat layer OCL may include at least one of an inorganic insulating layer and an organic insulating layer. For example, the overcoat layer OCL may include epoxy, but embodiments are not limited thereto.

In embodiments, the overcoat layer OCL may not be disposed on a top surface (or upper surface) of each of the first to third light emitting elements LD1″, LD2″, and LD3″. The first to third light emitting elements LD1″, LD2″, and LD3″ may protrude to the light functional layer LFL. The first to third light emitting elements LD1″, LD2″, and LD3″ may be at least partially positioned in second openings OP2 of a second bank BNK2. For example, a height of the top surface of each of the first to third light emitting elements LD1″, LD2″, and LD3″ from the substrate SUB may be higher than a height of a lowermost end of a reflective layer RFL from the substrate SUB. Accordingly, light emitted from the first to third light emitting elements LD1″, LD2″, and LD3″ may be provided to the light functional layer LFL at a relatively high ratio.

The cathode electrode CE″ may be disposed on the first to third light emitting elements LD1″, LD2″, and LD3″. The cathode electrode CE″ may be disposed (e.g., entirely disposed) on the first bank BNK1, the first to third light emitting elements LD1 “, LD2″, and LD3″, and the overcoat layer OCL. The cathode electrode CE″ may be in contact with the top surface (or upper surface) of the second semiconductor layer 30 of each of the first to third light emitting elements LD1″, LD2″, and LD3″. The cathode electrode CE″ may be connected (e.g., electrically connected) to the second power voltage node VSSN shown in FIG. 2. The second power voltage applied to the second power voltage node VSSN may be transferred to the first to third light emitting elements LD1″, LD2″, and LD3″ through the cathode electrode CE″.

The cathode electrode CE″ may be formed substantially transparent or translucent to satisfy a selected light transmittance. In embodiments, the cathode electrode CE″ may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the cathode electrode CE″ is not limited thereto.

The capping layer CPL may be disposed over the cathode electrode CE″. The capping layer CPL may protect components disposed under the capping layer CPL, such as the cathode electrode CE″ and the first to third light emitting elements LD1″, LD2″, and LD3″, from external moisture, humidity, and the like. The capping layer CPL may include at least one of silicon nitride, silicon oxide, silicon oxynitride, and a metal oxide such as aluminum oxide. However, the material of the capping layer CPL is not limited thereto.

The light functional layer LFL may be disposed on the capping layer CPL. The light functional layer LFL may include the second bank BNK2, the reflective layer RFL, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1. The second bank BNK2 may have the second openings OP2 overlapping the first openings OP1.

The second bank BNK2 may include a light blocking material, to prevent light mixture between adjacent sub-pixels and the first to third sub-pixels SP1″, SP2″, and SP3″. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second openings OP2. The reflective layer RFL may reflect incident light, and accordingly, light emission efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

It may be understood that emission areas EMA and a non-emission area NEMA of the first to third sub-pixels SP1″, SP2″, and SP3″ are defined by the second bank BNK2. An area overlapping the second bank BNK2 may correspond to the non-emission area NEMA. Areas overlapping the second openings OP2 of the second bank BNK2 may correspond to the emission areas EMA.

On a capping layer CPL, the third passivation layer PSV3 may be disposed in the second openings OP2. The third passivation layer PSV3 may protect components disposed under the third passivation layer PSV, and provide a flat top surface (or flat upper surface). The third passivation layer PSV3 may include the same material as any one of the first and second passivation layers PSV1 and PSV2, but embodiments are not limited thereto.

On the third passivation layer PSV3, the first and second light conversion patterns CCP1 and CCP2 and the light scattering pattern LSP may be disposed in the second openings OP2.

The first and second light conversion patterns CCP1 and CCP2 and the light scattering pattern LSP may include color conversion particles and/or light scattering particles. The color conversion particles may convert incident light into light of another color by changing a wavelength of the incident light. For example, the color conversion particles may scatter incident light. In embodiments, the color conversion particles may be quantum dots. The light scattering particles may scatter incident light.

In embodiments, the first to third light emitting elements LD1″, LD2″, and LD3″ may emit light of a blue color. The first light conversion pattern CCP1 may include first color conversion particles QD1 that convert light of the blue color into light of a red color. The second light conversion pattern CCP2 may include second color conversion particles QD2 that convert light of the blue color into light of a green color. The light scattering pattern LSP may include light scattering particles SCT which scatter light of the blue color so as to improve light emission efficiency. Accordingly, the first to third sub-pixels SP1″, SP2″, and SP3″ may be provided (or formed) as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

In embodiments, the first to third light emitting elements LD1″, LD2″, and LD3″ may emit lights of the red color, the green color, and the blue color, respectively. Each of the first and second light conversion patterns CCP1 and CCP2 and the light scattering pattern LSP may include the light scattering particles SCT. For example, the particles included in the first and second light conversion patterns CCP1 and CCP2 and the light scattering pattern LSP may be variously changed according to colors of lights emitted from the first to third light emitting elements LD1″, LD2″, and LD3″.

In embodiments, the first and second light conversion patterns CCP1 and CCP2 and the light scattering pattern LSP may be omitted.

The low refractive layer LRL may be disposed on the second bank BNK2, the reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. The low refractive layer LRL may refract or totally reflect light according to an incident angle of the corresponding light. The low refractive layer LRL may again provide light passing through the first and second light conversion patterns CCP1 and CCP2 and the light scattering pattern LSP to the first and second light conversion patterns CCP1 and CCP2 and the light scattering pattern LSP, and accordingly, the light conversion efficiency and light scattering efficiency of the first and second light conversion patterns CCP1 and CCP2 and the light scattering pattern LSP may be improved. In embodiments, the low refractive layer LRL may be omitted in an area corresponding to the third sub-pixel SP3″.

The color filter layer CFL may be disposed on the low refractive layer LRL. The color filter layer CFL may include the first to third color filters CF1, CF2, and CF3 and light blocking patterns LBP.

The first to third color filters CF1, CF2, and CF3 may overlap the first and second light conversion patterns CCP1 and CCP2 and the light scattering pattern LSP, respectively. Each of the first to third color filters CF1, CF2, and CF3 may selectively transmit light in a selected wavelength range therethrough. In case that the first sub-pixel SP1″ is a red sub-pixel, the first color filter CF1 may include a red color filter. In case that the second sub-pixel SP2″ is a green sub-pixel, the second color filter CF2 may include a green color filter. In case that the third sub-pixel SP3″ is a blue sub-pixel, the third color filter CF3 may include a blue color filter. The first to third color filters CF1, CF2, and CF3 may have a refractive index higher than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas (or light output areas) EMA and the non-emission area NEMA of the first and second sub-pixels SP1″, SP2″, and SP3″ are defined by the light blocking patterns LBP. An area overlapping the light blocking patterns LBP may correspond to the non-emission area NEMA. Areas not overlapping the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlapping each other. In another example, a light blocking pattern between the first and second color filters CF1 and CF2 among the light blocking patterns LBP may be formed as a multi-layer in which the first and second color filters CF1 and CF2 overlap each other, and a light blocking pattern between the second and third color filters CF2 and CF3 among the light blocking patterns LBP may be formed as a multi-layer in which the second and third color filters CF2 and CF3 overlap each other. Alight blocking pattern between the first color filter CF1 and a third color filter CF3 of an adjacent pixel may be formed as a multi-layer in which the first and third color filters CF1 and CF3 overlap each other. For example, each of the first to third color filters CF1, CF2, and CF3 may extend to the non-emission area NEMA to form the light blocking patterns LBP.

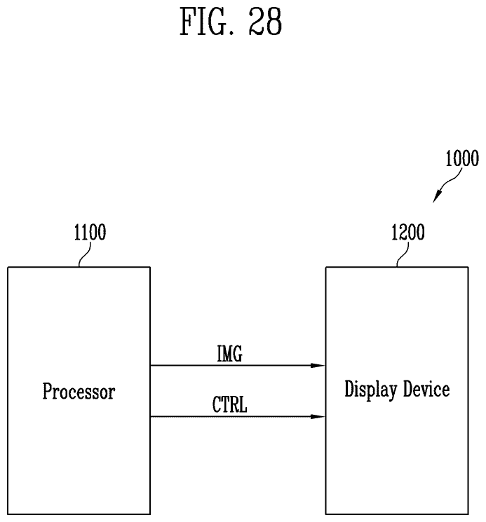

FIG. 28 is a schematic block diagram illustrating a display system in accordance with an embodiment.

Referring to FIG. 28, the display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be formed identical (or similar) to the display device DD described with reference to FIG. 1. The image data IMG and the control signal CTRL may be provided (or formed) as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

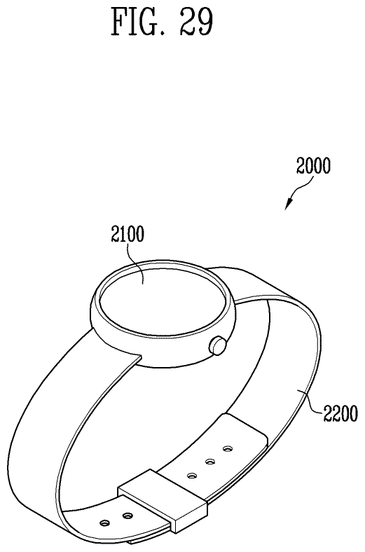

FIGS. 29 to 32 are schematic perspective views illustrating application examples of the display system shown in FIG. 28.

Referring to FIG. 29, the display system 1000 shown in FIG. 28 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information may be provided to the user.

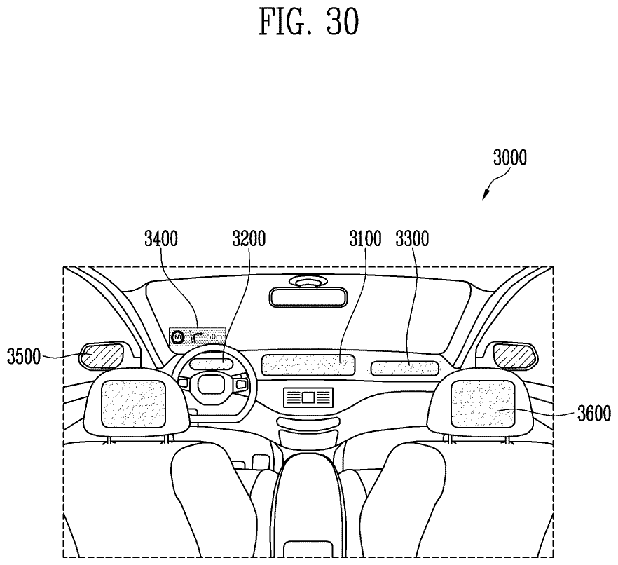

Referring to FIG. 30, the display system 1000 shown in FIG. 28 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a rear seat display 3600, which are provided in the vehicle.

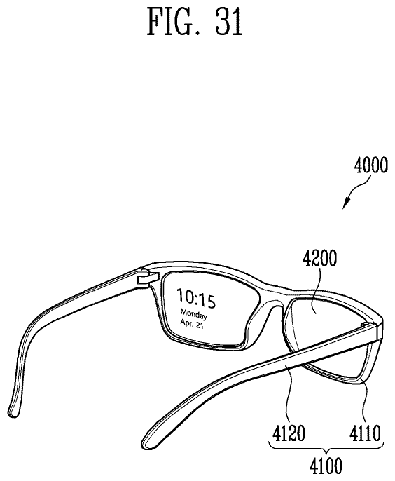

Referring to FIG. 31, the display system 1000 shown in FIG. 28 may be applied to smart glasses 4000. The smart glasses 4000 may be a wearable electronic device which is worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. For example, a projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

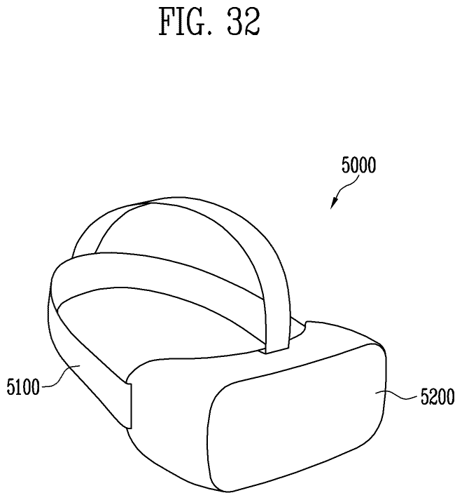

Referring to FIG. 32, the display system 1000 shown in FIG. 28 may be applied to a head mounted display device 5000.

The head mounted display device 5000 may be a wearable electronic device which is worn on the head of a user. For example, the head mounted display device 5000 may be a wearable device for virtual reality (VR) or mixed reality (MR).

The head mounted display device 5000 may include a head mounted band 5100 and a display device accommodating case 5200. The head mounted band 5100 may be connected to the display device accommodating case 5200. The head mounted band 5100 may include a horizontal band and/or a vertical band, used to fix the head mounted display device 5000 to the head of the user. The horizontal band may surround a side portion of the head of the user, and the vertical band may surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

In the light emitting element in accordance with the disclosure, a bonding electrode may define (or include) an indented portion and an outgassing path extending from the indented portion. Accordingly, in case that the bonding electrode is bonded to an electrode connected to a pixel circuit of a display device, an air between the bonding electrode and the electrode may be exhausted through the outgassing path. Thus, the bonding reliability of the light emitting element may be improved.

In the light emitting element in accordance with the disclosure, a bonding electrode may define (or include) a step difference in a thickness direction. In case that the bonding electrode is bonded to an electrode connected to a pixel circuit of a display device, any disclosed space between the bonding electrode and the electrode is not defined by the step difference. Thus, the bonding reliability of the light emitting element may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. Alight emitting element comprising:
a light emitting stack member including a first semiconductor layer, an active layer, and a second semiconductor layer, which are sequentially stacked in a thickness direction;
an insulative film covering a portion of an outer circumferential surface of the light emitting stack member;
a first bonding electrode including a first indented portion indented in the thickness direction, the first bonding electrode being electrically connected to the first semiconductor layer in an area in which the first indented portion is formed; and
a second bonding electrode spaced apart from the first bonding electrode, the second bonding electrode being electrically connected to the second semiconductor layer,
wherein the first bonding electrode includes a first outgassing path which is indented in the thickness direction and extends from the first indented portion to a side surface of the first bonding electrode.

2. The light emitting element of claim 1, wherein the first outgassing path is provided in plurality.

3. The light emitting element of claim 2, wherein at least some of the plurality of first outgassing paths extend in different directions.

4. The light emitting element of claim 1, wherein
the insulative film includes a first penetration hole exposing a portion of the first semiconductor layer, and
the first penetration hole overlaps the first indented portion.

5. The light emitting element of claim 1, wherein the second bonding electrode includes a second indented portion indented in the thickness direction, and is electrically connected to the second semiconductor layer in an area in which the second indented portion is formed.

6. The light emitting element of claim 5, wherein the second bonding electrode includes a second outgassing path which is indented in the thickness direction and extends from the second indented portion to a side surface of the second bonding electrode.

7. The light emitting element of claim 6, wherein the second outgassing path is provided in plurality.

8. The light emitting element of claim 7, wherein at least some of the plurality of second outgassing paths extend in different directions.

9. The light emitting element of claim 5, wherein
the first semiconductor layer and the active layer include a second penetration hole exposing a portion of the second semiconductor layer, and
the second penetration hole overlaps the second indented portion.

10. The light emitting element of claim 9, wherein the insulative film directly covers inner side surfaces of the first semiconductor layer and the active layer, which include the second penetration hole.

11. A light emitting element comprising:
a light emitting stack member including a first semiconductor layer, an active layer, and a second semiconductor layer, which are sequentially stacked in a thickness direction;
an insulative film covering a portion of an outer circumferential surface of the light emitting stack member; and
a bonding electrode including an indented portion indented in the thickness direction and an outgassing path indented in the thickness direction, the bonding electrode being electrically connected to the first semiconductor layer in an area in which the indented portion is formed,
wherein the outgassing path extends from the indented portion to a side surface of the bonding electrode.

12. The light emitting element of claim 11, wherein the outgassing path is provided in plurality.

13. The light emitting element of claim 11, wherein
the insulative film includes a penetration hole exposing a portion of the first semiconductor layer, and
the penetration hole overlaps the indented portion.

14. The light emitting element of claim 11, wherein the light emitting stack member has a pillar shape.

15. Alight emitting element comprising:
a light emitting stack member including a first semiconductor layer, an active layer, and a second semiconductor layer, which are sequentially stacked in a thickness direction;
an insulative film covering a portion of a lower surface of the first semiconductor layer;
a first bonding electrode extending from the insulative film covering the portion of the lower surface of the first semiconductor layer to a side surface of the light emitting stack member, the first bonding electrode being electrically connected to the first semiconductor layer; and
a second bonding electrode extending from the insulative film covering the portion of the lower surface of the first semiconductor layer to an opposite side surface of the light emitting stack member, the second bonding electrode being electrically connected to the second semiconductor layer,
wherein, in the first bonding electrode, a first step difference is formed in the thickness direction between a (1-1)th bonding portion overlapping the insulative film covering the portion of the lower surface of the first semiconductor layer and a (1-2)th bonding portion adjacent to the side surface of the light emitting stack member.

16. The light emitting element of claim 15, wherein the insulative film exposes another portion of the lower surface of the first semiconductor layer, which is adjacent to the side surface of the light emitting stack member.

17. The light emitting element of claim 16, wherein the (1-2)th bonding portion overlaps the another portion of the lower surface of the first semiconductor layer.

18. The light emitting element of claim 15, wherein, in the second bonding electrode, a second step difference is formed in the thickness direction between a (2-1)th bonding portion overlapping the insulative film covering the portion of the lower surface of the first semiconductor layer and a (2-2)th bonding portion adjacent to the opposite side surface of the light emitting stack member.

19. The light emitting element of claim 18, wherein
the second semiconductor layer includes:
a first portion overlapping the first semiconductor layer and the active layer in plan view and
a second portion which is disposed on the first portion and has an area which is greater than an area of the first portion in plan view,
in an area adjacent to the opposite side surface of the light emitting stack member, the second portion does not overlap the first portion in plan view, and
wherein the (2-2)th bonding portion is electrically connected to the second portion not overlapping the first portion under the second portion.

20. The light emitting element of claim 18, wherein the second step difference is greater than the first step difference.

21. An electronic device comprising:
a processor to provide input image data; and
a display device to display an image based on the input image data,
wherein the display device includes a light emitting element, and
wherein the light emitting element includes:
a light emitting stack member including a first semiconductor layer, an active layer, and a second semiconductor layer, which are sequentially stacked in a thickness direction;
an insulative film covering a portion of an outer circumferential surface of the light emitting stack member;
a first bonding electrode including a first indented portion indented in the thickness direction, the first bonding electrode being electrically connected to the first semiconductor layer in an area in which the first indented portion is formed; and
a second bonding electrode spaced apart from the first bonding electrode, the second bonding electrode being electrically connected to the second semiconductor layer, and
wherein the first bonding electrode includes a first outgassing path which is indented in the thickness direction and extends from the first indented portion to a side surface of the first bonding electrode.
